(19) United States
(12) Patent Application Publication
(10) Pub. No.: US 2020/0116443 A1
(43) Pub. Date: Apr. 16, 2020

(54) HIGHLY CONDUCTIVE GRAPHITIC THICK FILMS AND METHOD OF PRODUCTION

(71) Applicant: Nanotek Instruments, Inc., Dayton, OH (US)

(72) Inventors: Yi-jun Lin, Taoyuan City (TW); Yanbo Wang, Xenia, OH (US); Bor Z. Jang, Centerville, OH (US)

(73) Assignee: Nanotek Instruments, Inc., Dayton, OH (US)

(21) Appl. No.: 16/156,622

(22) Filed: Oct. 10, 2018

(51) Int. Cl. F28F 21/02; B32B 9/04; B32B 7/12; H05K 9/00; H05K 7/20

(52) U.S. Cl. CPC F28F 21/02; B32B 9/04; B32B 7/12; B32B 2307/302; H05K 7/2039; B32B 2307/202; B32B 2307/212; H05K 9/0088

(57) ABSTRACT

Provided is a multi-layer graphitic laminate comprising at least two graphitic films or graphene layers and a layer of conductive adhesive disposed between the two graphitic films or graphene layers and bonded thereto, wherein the conductive adhesive layer comprises graphene sheets or expanded graphite flakes disperse in or bonded by an adhesive resin, and the graphene sheets or expanded graphite flakes occupy a weight fraction from 0.01% to 99% based on the total conductive adhesive weight.

### FIELD OF THE INVENTION

The present invention relates generally to the field of graphitic materials for electromagnetic interference (EMI) shielding and heat dissipation applications and, more particularly, to an electrically and thermally conductive graphitic thick film obtained by laminating graphitic films or graphene layers together.

### BACKGROUND OF THE INVENTION

Advanced EMI-shielding and thermal management materials are becoming more and more critical for today's microelectronic, photonic, and photovoltaic systems. These systems require shielding against EMI from external sources. These systems can be sources of electromagnetic interference to other sensitive electronic devices and, hence, must be shielded. Materials for EMI shielding applications must be electrically conducting.

Further, as new and more powerful chip designs and light-emitting diode (LED) systems are introduced, they consume more power and generate more heat. This has made thermal management a crucial issue in today's high performance systems. Systems ranging from active electronically scanned radar arrays, web servers, large battery packs for personal consumer electronics, wide-screen displays, and solid-state lighting devices all require high thermal conductivity materials that can dissipate heat more efficiently. Furthermore, many microelectronic devices (e.g. smart phones, flat-screen TVs, tablets, and laptop computers) are designed and fabricated to become increasingly smaller, thinner, lighter, and tighter. This further increases the difficulty of thermal dissipation. Actually, thermal management challenges are now widely recognized as the key barriers to industry's ability to provide continued improvements in device and system performance.

Heat sinks are components that facilitate heat dissipation from the surface of a heat source, such as a CPU or battery in a computing device, to a cooler environment, such as ambient air. Typically, heat transfer between a solid surface and the air is the least efficient within the system, and the solid-air interface thus represents the greatest barrier for heat dissipation. A heat sink is designed to enhance the heat transfer efficiency between a heat source and the air mainly through increased heat sink surface area that is in direct contact with the air. This design enables a faster heat dissipation rate and thus lowers the device operating temperature.

Materials for thermal management applications (e.g. as a heat sink or heat spreader) must be thermally conducting. Typically, heat sinks are made from a metal, especially copper or aluminum, due to the ability of metal to readily transfer heat across its entire structure. Cu and Al heat sinks are formed with fins or other structures to increase the surface area of the heat sink, often with air being forced across or through the fins to facilitate dissipation of heat to the air. However, there are several major drawbacks or limitations associated with the use of metallic heat sinks. One drawback relates to the relatively low thermal conductivity of a metal (<400 W/mK for Cu and 80-200 W/mK for Al alloy). In addition, the use of copper or aluminum heat sinks can present a problem because of the weight of the metal, particularly when the heating area is significantly smaller than that of the heat sink. For instance, pure copper weighs 8.96 grams per cubic centimeter (g/cm³) and pure aluminum weighs 2.70 g/cm³. In many applications, several heat sinks need to be arrayed on a circuit board to dissipate heat from a variety of components on the board. If metallic heat sinks are employed, the sheer weight of the metal on the board can increase the chances of the board cracking or of other undesirable effects, and increases the weight of the component itself. Many metals do not exhibit a high surface thermal emissivity and thus do not effectively dissipate heat through the radiation mechanism.

Thus, there is a strong need for a non-metallic heat sink system effective for dissipating heat produced by a heat source such as a CPU and battery in a device. The heat sink system should exhibit a higher thermal conductivity and/or a higher thermal conductivity-to-weight ratio as compared to metallic heat sinks. These heat sinks must also be mass-producible, preferably using a cost-effective process. This processing ease requirement is important since metallic heat sinks can be readily produced in large quantities using scalable techniques such as extrusion, stamping, and die casting.

It is an object of the present invention to provide graphitic films (laminates) that exhibit a combination of exceptional thermal conductivity, electrical conductivity, and mechanical strength unmatched by any material of comparable thickness range.

Another object of the present invention is to provide a cost-effective process for producing a thermally conductive graphitic laminate by laminating multiple graphitic films (produced from carbonization and graphitization of a polymer film or a graphene-filled polymer film) or multiple graphene layers together.

### SUMMARY OF THE INVENTION

The present invention provides a multi-layer graphitic laminate comprising at least two graphitic films (or graphene layers) and a layer of conductive adhesive disposed between the two graphitic films (or graphene layers) and bonded thereto, wherein the conductive adhesive layer comprises graphene sheets or expanded graphite flakes bonded by or dispersed in an adhesive resin, and the graphene sheets or expanded graphite flakes occupy a weight fraction from 0.01% to 99% based on the total conductive adhesive layer weight.

Preferably, the laminate has a thickness from 20 μm to 500 μm and/or the conductive adhesive layer has a thickness from 5 nm to 15 μm. Preferably, the graphitic films or graphene layers have a thickness greater than 20 μm (preferably greater than 25 μm, and more preferably greater than 30 μm). The conductive adhesive layer is typically from 5 nm to 15 μm, more typically from 50 nm to 5 μm, further more typically from 100 nm to 2 μm, and most desirably less than 1 μm.

In certain embodiments, the multi-layer graphitic laminate has an in-plane thermal conductivity from 1,200 to 1,750 W/mK (more typically from 1,500 to 1,750 W/mK), an in-plane electric conductivity from 2,000 to 20,000 S/cm (more typically from 3,000 to 20,000 S/cm), or a physical density from 1.5 g/cm³ to 2.26 g/cm³ when comprising no metallic, ceramic, or glass filler dispersed therein.

In the multi-layer graphitic laminate, the graphene sheets in the conductive adhesive layer may contain single-layer or few-layer graphene sheets selected from a pristine graphene material (defined as graphene sheets having essentially zero % of non-carbon elements), or a non-pristine graphene material (typically having 0.001% to 50% by weight of non-carbon elements and more typically up to 25% of non-carbon elements). The non-pristine graphene may be selected from graphene oxide, reduced graphene oxide, graphene fluoride, graphene chloride, graphene bromide, graphene iodide, hydrogenated graphene, nitrogenated graphene, doped graphene, chemically functionalized graphene, or a combination thereof.

Processes for making graphene sheets are taught in U.S. Pat. Nos. 7,071,258, 7,566,410, 7,662,321, 7,785,492 and 7,892,514, 7,790,285, 8,883,114, and 8,696,938, which are incorporated by reference, in their entirety, for the purpose of teaching methods of making graphene sheets and graphene paper. Processes for making expanded graphite are taught in U.S. Pat. Nos. 7,758,783, 7,824,651, 8,132,746, 8,501,307, and 8,753,539, which are incorporated by reference, in their entirety, for the purpose of teaching methods of making expanded graphite.

It may be noted that the graphitic films obtained from carbonization and graphitization of polymer films and the graphene films obtained from thermally treated films of coated/cast graphene sheets are fundamentally distinct in terms of the structure, crystal sizes (thickness and lateral dimensions), grain boundary amounts, defect types and populations, etc. and, as such, the properties (e.g. electrical and thermal conductivities) are different. They represent two distinct classes of materials.

In certain embodiments, the graphene sheets in the conductive adhesive resin layer or in the constituent graphene layers of a laminate comprise chemically functionalized graphene sheets having a chemical functional group selected from alkyl or aryl silane, alkyl or aralkyl group, hydroxyl group, carboxyl group, carboxylic group, amine group, sulfonate group (—SO₃H), aldehydic group, quinoidal, fluorocarbon, or a combination thereof. The chemical functional group may be attached to the edge of a surface of a graphene sheet.

In certain embodiments, the graphene sheets comprise chemically functionalized graphene sheets having a chemical functional group selected from an oxygenated group selected from the group consisting of hydroxyl, peroxide, ether, keto, and aldehyde.

In some embodiments, the expanded graphite flakes in the conductive adhesive layer of the multi-layer graphitic laminate have a thickness from 100 nm to 1 μm and/or chemically functionalized. The chemical functional groups may be the same or different than the functional groups attached to graphene sheets as described above.

The adhesive resin may include an ester resin, a neopentyl glycol (NPG), ethylene glycol (EG), isophthalic acid, a terephthalic acid, a urethane resin, a urethane ester resin, an acrylic resin, an acrylic urethane resin, or a combination thereof.

In some embodiments, the adhesive resin contains a curing agent and/or a coupling agent in an amount of 1 to 30 parts by weight based on 100 parts by weight of the adhesive resin.

The adhesive resin contains a thermally curable resin may contain a poly-functional epoxy monomer selected from diglycerol tetraglycidyl ether, dipentaerythritol tetraglycidyl ether, sorbitol polyglycidyl ether, polyglycerol polyglycidyl ether, pentaerythritol polyglycidyl ether, or a combination thereof.

In some embodiments, the adhesive resin contains a thermally curable resin containing a bi- or tri-functional epoxy monomer selected from the group consisting of trimethylolethane triglycidyl ether, trimethylolmethane triglycidyl ether, trimethylolpropane triglycidyl ether, triphenylolmethane triglycidyl ether, trisphenol triglycidyl ether, tetraphenylol ethane triglycidyl ether, tetraglycidyl ether of tetraphenylol ethane, p-aminophenol triglycidyl ether, 1,2,6-hexanetriol triglycidyl ether, glycerol triglycidyl ether, diglycerol triglycidyl ether, glycerol ethoxylate triglycidyl ether, castor oil triglycidyl ether, propoxylated glycerine triglycidyl ether, ethylene glycol diglycidyl ether, 1,4-butanediol diglycidyl ether, neopentyl glycol diglycidyl ether, cyclohexanedimethanol diglycidyl ether, dipropylene glycol diglycidyl ether, polypropylene glycol diglycidyl ether, dibromoneopentyl glycol diglycidyl ether, hydrogenated bisphenol A diglycidyl ether, (3,4-epoxycyclohexane) methyl 3,4-epoxycylohexylcarboxylate, and mixtures thereof.

The adhesive resin may contain an UV radiation curable resin or lacquer selected from acrylate and methacrylate oligomers, (meth)acrylate (acrylate and methacrylate), polyhydric alcohols and their derivatives having (meth)acrylate functional groups, including ethoxylated trimethylolpropane tri(meth)acrylate, tripropylene glycol di(meth)acrylate, trimethylolpropane tri(meth)acrylate, diethylene glycol di(meth)acrylate, pentaerythritol tetra(meth)acrylate, pentaerythritol tri(meth)acrylate, dipentaerythritol hexa(meth)acrylate, 1,6-hexanediol di(meth)acrylate, or neopentyl glycol di(meth)acrylate and mixtures thereof, and acrylate and methacrylate oligomers derived from low-molecular weight polyester resin, polyether resin, epoxy resin, polyurethane resin, alkyd resin, spiroacetal resin, epoxy acrylates, polybutadiene resin, and polythiol-polyene resin.

In some embodiments, the adhesive resin contains a conductive polymer selected from the group consisting of polydiacetylene, polyacetylene (PAc), polypyrrole (PPy), polyaniline (PAni), polythiophene (PTh), polyisothionaphthene (PITN), polyheteroarylenvinylene (PArV), wherein the heteroarylene group is selected from thiophene, furan or pyrrole, poly-p-phenylene (PpP), polyphthalocyanine (PPhc) and the like, and their derivatives, and combinations thereof.

The graphitic films in a multi-layer graphitic laminate preferably exhibit a degree of graphitization no less than 60% and/or a mosaic spread value less than 0.7. Further preferably, the graphitic film exhibits a degree of graphitization no less than 90% and/or a mosaic spread value less than 0.4.

The invention also provides an electronic device containing the presently invented multi-layer graphitic laminate as a heat-dissipating element therein.

The present invention also provides a process for producing a multi-layer graphitic laminate, the process comprising:
A) providing one or a plurality of graphitic films (e.g. those produced by carbonizing and graphitizing polymer films) or graphene layers, wherein at least one of the graphene layers is selected from a sheet of graphene paper, graphene fabric, graphene film, graphene membrane, or graphene foam and the graphene is selected from pristine graphene, graphene oxide, reduced graphene oxide, graphene fluoride, graphene chloride, graphene bromide, graphene iodide, hydrogenated graphene, nitrogenated graphene, doped graphene, chemically functionalized graphene, or a combination thereof; and
B) laminating at least two of the graphitic films and graphene layers and a conductive adhesive layer disposed between the two graphitic films or graphene layers to form the multi-layer graphitic laminate, wherein the conductive adhesive layer comprises graphene sheets or expanded graphite flakes dispersed in or bonded by an adhesive resin and the graphene sheets or expanded graphite flakes occupy a weight fraction from 0.01% to 99% (preferably from 0.1% to 90%, further preferably from 1% to 60%) based on the total conductive adhesive weight.

In certain embodiments, the step of providing one or a plurality of graphitic films may comprise a procedure of subjecting one or a plurality of precursor polymer films to carbonization and graphitization to produce the one or plurality of graphitic films, wherein the precursor polymer film is selected from the group consisting of polyimide, polyamide, phenolic resin, polyoxadiazole, polybenzoxazole, polybenzobisoxazole, polythiazole, polybenzothiazole, polybenzobisthiazole, poly(p-phenylene vinylene), polybenzimidazole, polybenzobisimidazole, polyacrylonitrile, and combinations thereof. In some embodiments, the precursor polymer film is a neat resin containing no additive. Optionally, the precursor polymer film may contain 0.1% to 50% of graphene sheets or expanded graphite flakes dispersed therein.

In certain embodiments, the process further comprises a step of compressing the graphitic films or the graphene layers, during or after the carbonization or graphitization, to obtain the multi-layer graphitic laminate having a physical density from 1.5 g/cm³ to 2.26 g/cm³, more typically at least 1.7 g/cm³, and most typically at least 1.9 g/cm³.

Preferably, the process is a continuous process that includes continuously or intermittently feeding the precursor polymer film from one end of a carbonization or graphitization zone and retreating the graphitic film from another end of the carbonization or graphitization zone (e.g. entering from one end of a carbonization or graphitization furnace and leaving from another end of the furnace). Preferably, the graphitization zone is at least 5 meters long. In an embodiment, the graphitization zone is at a temperature from 2,500 to 3,200° C. and the residence time is from 2 hours to 12 hours.

Preferably, the precursor polymer film is under a compression stress while residing in the carbonization or graphitization zone. In a preferred embodiment, the precursor polymer film is supported on a first refractory material plate and covered by a second refractory material plate to exert a compressive stress to the precursor polymer film while residing in the carbonization or graphitization zone. The first refractory material or second refractory material may be selected from a thermally stable material, such as graphite, a refractory metal, or a carbide, oxide, boride, or nitride of a refractory metal element selected from tungsten, zirconium, tantalum, niobium, molybdenum, tantalum, or rhenium.

In a particularly advantageous embodiment, the precursor polymer film contains multiple sheets of a graphene material dispersed therein, wherein the graphene material is selected from pristine graphene, oxidized graphene, reduced graphene oxide, fluorinated graphene, hydrogenated graphene, doped graphene, chemically functionalized graphene, or a combination thereof. The graphene material can comprise a single-layer graphene sheet or a multi-layer graphene platelet with a thickness less than 10 nm. The graphene material can comprise a multi-layer graphene platelet with a thickness less than 4 nm. In a desired embodiment, the graphene material comprises a single-layer pristine graphene sheet or a multi-layer pristine graphene platelet with a thickness less than 10 nm and the pristine graphene sheet or pristine graphene platelet contains no oxygen and is produced from a process that does not involve oxidation. The presence of these graphene sheets can significantly reduce the required heat treatment temperatures and times of a polymer film.

In yet another embodiment, the precursor polymer film or other carbon/graphite precursor film contains expanded graphite flakes having a thickness greater than 100 nm.

In an embodiment, the precursor polymer does not have to have a high carbon yield; instead, it can still work even if the polymer has an intrinsic char yield of less than 50% (or even less than 40%, typically from 5% to 40%), provided that this polymer is reinforced with sheets of graphene or expanded graphite flakes (EP), as opposed to just the neat polymer alone.

If the graphitization temperature is less than 2,500° C., the resulting solid graphitic film typically has an inter-graphene spacing less than 0.337 nm (as determined by X-ray diffraction), a thermal conductivity of at least 1,200 W/mK, an electrical conductivity no less than 8,000 S/cm, a physical density greater than 1.9 g/cm³, and/or a tensile strength greater than 35 MPa. When the graphitization temperature is higher than 2,500° C., the resulting graphitic film typically has an inter-graphene spacing less than 0.336 nm, a thermal conductivity of at least 1,300 W/mK, an electrical conductivity no less than 10,000 S/cm, a physical density greater than 2.0 g/cm³, and/or a tensile strength greater than 40 MPa.

In an embodiment, the graphitic film exhibits an inter-graphene spacing less than 0.337 nm and a mosaic spread value less than 1.0. In another embodiment, the graphitic film exhibits a degree of graphitization no less than 60% and/or a mosaic spread value less than 0.7. In yet another embodiment, the graphitic film exhibits a degree of graphitization no less than 90% and/or a mosaic spread value less than 0.4.

In some embodiments, the step of laminating comprises a step of dispensing or depositing said conductive adhesive onto a surface of at least one of the graphitic films or graphene layers. The step of dispensing or depositing may comprise a procedure of spraying, casting, coating, printing, or a combination thereof.

In some embodiments, the step of laminating comprises dispensing or depositing a thermally curable adhesive resin onto a surface of at least one of the graphitic films or graphene layers and thermally curing said adhesive resin after said adhesive resin is laminated between two graphitic films or graphene layers. The thermally curable adhesive resin may, for instance, contain a polyfunctional epoxy monomer selected from diglycerol tetraglycidyl ether, dipentaerythritol tetraglycidyl ether, sorbitol polyglycidyl ether, polyglycerol polyglycidyl ether, pentaerythritol polyglycidyl ether, or a combination thereof.

In some embodiments, the step of laminating comprises dispensing or depositing an UV-curable adhesive resin onto a surface of at least one of the graphitic films or graphene layers and operating an UV means to initiate curing of the adhesive resin prior to laminating the adhesive resin between two graphitic films or graphene layers.

In certain embodiments, the adhesive resin contains a conductive polymer selected from the group consisting of polydiacetylene, polyacetylene (PAc), polypyrrole (PPy), polyaniline (PAni), polythiophene (PTh), polyisothionaphthene (PITN), polyheteroarylenvinylene (PArV), wherein the heteroarylene group is selected from thiophene, furan or pyrrole, poly-p-phenylene (PpP), polyphthalocyanine (PPhc) and the like, and their derivatives, and combinations thereof.

### BRIEF DESCRIPTION OF THE DRAWINGS

FIG. 1(A) A flow chart illustrating various prior art processes of producing exfoliated graphite products (expanded graphite flakes, flexible graphite foils and flexible graphite composites) and pyrolytic graphite film (bottom portion); (B) Schematic drawing illustrating the processes for producing paper, mat, film, and membrane of simply aggregated graphite flakes or graphene sheets/platelets.

FIG. 2(A) A SEM image of a graphite worm sample after thermal exfoliation of graphite intercalation compounds (GICs) or graphite oxide powders; (B) An SEM image of a cross-section of a flexible graphite foil, showing many graphite flakes with orientations not parallel to the flexible graphite foil surface and also showing many defects, kinked or folded flakes.

FIG. 3(A) A SEM image of a graphitic film derived from graphene sheet-PI composite.

FIG. 3(B) A SEM image of a cross-section of a graphene paper/film prepared from discrete graphene sheets/platelets using a paper-making process (e.g. vacuum-assisted filtration). This latter image shows many discrete graphene sheets being folded or interrupted (not integrated), with orientations not parallel to the film/paper surface and having many defects or imperfections.

FIG. 4 Chemical reactions associated with production of PBO.

FIG. 5(A) The thermal conductivity values of a series of graphitic films derived from NGP-PBO films of various weight fractions of NGPs (from 0% to 100%).

FIG. 5(B) The thermal conductivity values of a series of graphitic films derived from expanded graphite flake-PBO (EP-PBO) films of various weight fractions of NGPs.

FIG. 5(C) Thermal conductivity comparison between graphitic films obtained from EP-PBO and NGP-PBO films (via direct graphitization).

FIG. 6(A) Thermal conductivity values of a series of graphitic films derived from NGP-PI films (66% NGP+34% PI), NGP paper alone, and PI film alone prepared under various heat treatment conditions (direct graphitization vs. carbonization+graphitization).

FIG. 6(B) Electrical conductivity values of a series of graphitic films derived from NGP-PI films (66% NGP+34% PI), NGP paper alone, and PI film alone prepared under various heat treatment conditions (direct graphitization vs. carbonization+graphitization).

FIG. 7(A) The thermal conductivity values of a series of graphitic films derived from NGP-PF films (90% NGP+10% PF), NGP paper alone, and PF film alone prepared at various final heat treatment temperatures, along with a curve of thermal conductivity according to the predictions of a rule-of-mixture law.

FIG. 7(B) The thermal conductivity values of a series of graphitic films derived from EP-PF films (90% EP+10% PF), EP paper alone, PF film alone, and theoretical predictions.

FIG. 8 The electric conductivity values of a series of graphitic films derived from NGP-PBI films of various weight fractions of NGPs (from 0% to 100%).

FIG. 9 The tensile strength values of NGP-PI derived films, PI-derived films, and NGP paper samples plotted as a function of the graphitization temperature.

FIG. 10 The thermal conductivity values of a series of graphitic 3-layer laminates each containing a conductive adhesive layer (having either 10% by weight of graphene sheets or 10% by weight of expanded graphite flakes dispersed therein) sandwiched between two graphitic films, wherein the adhesive layer has a thickness varied from 10 nm to 15 μm.

FIG. 11 The electrical conductivity values of a series of graphitic 3-layer laminates each containing a conductive adhesive layer (having either 10% by weight of graphene sheets or 10% by weight of expanded graphite flakes dispersed therein) sandwiched between two graphitic films, wherein the adhesive layer has a thickness varied from 10 nm to 15 μm.

FIG. 12 The thermal conductivity values of a series of graphitic 3-layer laminates each containing a conductive adhesive layer (having either graphene sheets or expanded graphite flakes dispersed therein) sandwiched between two graphitic films, wherein the adhesive layer has a thickness of 1 μm and graphene/expanded graphite proportion being varied from 0.5% to 90%.

### DESCRIPTION OF THE PREFERRED EMBODIMENTS

The present invention provides a multi-layer graphitic laminate comprising at least two carbon-based layers selected from graphitic films, graphene layers and a layer of conductive adhesive disposed between the carbon-based layers and bonded thereto, wherein the conductive adhesive layer comprises graphene sheets or expanded graphite flakes and an adhesive resin, and the graphene sheets or expanded graphite flakes occupy a weight fraction from 0.01% to 99% based on the total conductive adhesive weight. Preferably, the laminate has a thickness from 20 μm to 500 μm and/or the conductive adhesive layer has a thickness from 5 nm to 15 μm (most preferably no thicker than 1 μm). Preferably, the constituent graphitic films or graphene layers have a thickness greater than 20 μm (preferably greater than 25 μm, and more preferably greater than 30 μm).

The multi-layer graphitic laminate may comprise two more graphitic films, two or more graphene layers, or a combination of graphitic films and graphene layers.

Due to its exceptional thermal conductivity and electrical properties, the invented multi-layer graphitic laminate can be used as an advanced EMI-shielding and thermal management material in microelectronic, photonic, and photovoltaic systems.

In the multi-layer graphitic laminate, the graphene sheets in the conductive adhesive layer or those in the constituent graphene layers (graphene paper, graphene paper, graphene fabric, etc.) may contain single-layer or few-layer graphene sheets selected from a pristine graphene material (defined as graphene sheets having essentially zero % of non-carbon elements), or a non-pristine graphene material (typically having 0.001% to 50% by weight of non-carbon elements and more typically up to 25% of non-carbon elements). The non-pristine graphene may be selected from graphene oxide, reduced graphene oxide, graphene fluoride, graphene chloride, graphene bromide, graphene iodide, hydrogenated graphene, nitrogenated graphene, doped graphene, chemically functionalized graphene, or a combination thereof. The chemically functionalized graphene sheets may contain some chemical functional groups attached to sheet surfaces or edges.

In some embodiments, the conductive adhesive layer of the multi-layer graphitic laminate comprises expanded graphite flakes dispersed in an adhesive resin. The expanded graphite flakes typically have a thickness from 100 nm to 1 μm. The expanded graphite flakes may be chemically functionalized. The chemical functional groups may be the same or different than the functional groups attached to graphene sheets.

In certain embodiments, the chemical functional group is selected from alkyl or aryl silane, alkyl or aralkyl group, hydroxyl group, carboxyl group, carboxylic group, amine group, sulfonate group (—SO₃H), aldehydic group, quinoidal, fluorocarbon, or a combination thereof. The chemical functional group may be attached to the edge of a surface of a graphene sheet.

In certain embodiments, the chemical functional group is selected from a derivative of an azide compound selected from the group consisting of 2-azidoethanol, 3-azidopropan-1-amine, 4-(2-azidoethoxy)-4-oxobutanoic acid, 2-azidoethyl-2-bromo-2-methylpropanoate, chlorocarbonate, azidocarbonate, dichlorocarbene, carbene, aryne, nitrene, (R-)-oxycarbonyl nitrenes, where R=any one of the following groups,

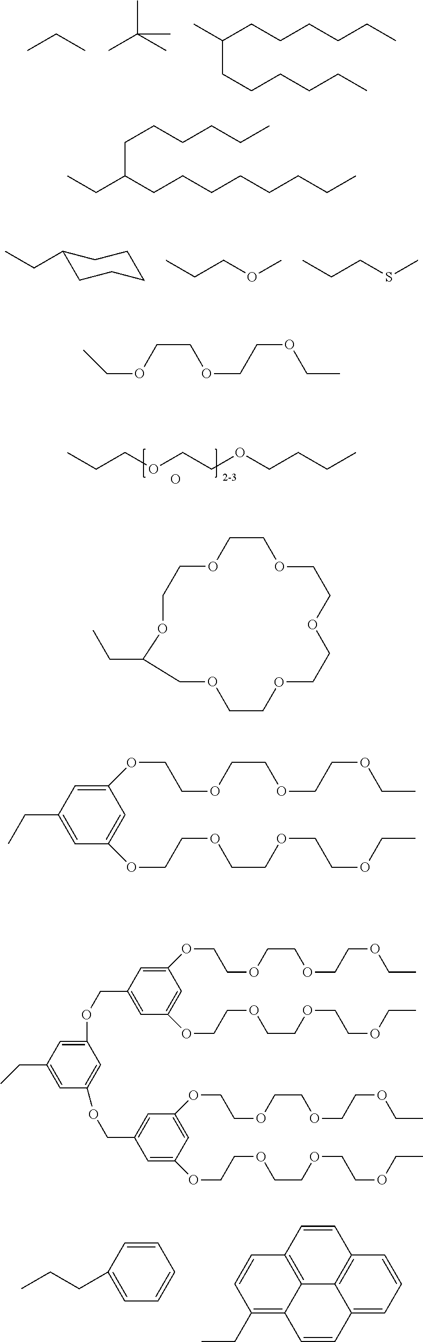

and combinations thereof.

In certain embodiments, the chemical functional group is selected from an oxygenated group selected from the group consisting of hydroxyl, peroxide, ether, keto, and aldehyde.

In certain embodiments, the chemical functional group is selected from the group consisting of —SO₃H, —COOH, —NH₂, —OH, —R′CHOH, —CHO, —CN, —COCl, halide, —COSH, —SH, —COOR′, —SR′, —SiR′₃, —Si(—OR′—)_{y}R′₃-y, —Si(—O—SiR′₂—)OR′, —R″, Li, AlR′₂, Hg—X, TlZ₂ and Mg—X; wherein y is an integer equal to or less than 3, R′ is hydrogen, alkyl, aryl, cycloalkyl, or aralkyl, cycloaryl, or poly(alkylether), R″ is fluoroalkyl, fluoroaryl, fluorocycloalkyl, fluoroaralkyl or cycloaryl, X is halide, and Z is carboxylate or trifluoroacetate, and combinations thereof.

In certain embodiments, the chemical functional group is selected from the group consisting of amidoamines, polyamides, aliphatic amines, modified aliphatic amines, cycloaliphatic amines, aromatic amines, anhydrides, ketimines, diethylenetriamine (DETA), triethylene-tetramine (TETA), tetraethylene-pentamine (TEPA), polyethylene polyamine, polyamine epoxy adduct, phenolic hardener, non-brominated curing agent, non-amine curatives, and combinations thereof.

In certain embodiments, the chemical functional group is selected from OY, NHY, O═C—OY, P═C—NR′Y, O═C—SY, O═C—Y, —CR′1-OY, N′Y or C′Y, and Y is a functional group of a protein, a peptide, an amino acid, an enzyme, an antibody, a nucleotide, an oligonucleotide, an antigen, or an enzyme substrate, enzyme inhibitor or the transition state analog of an enzyme substrate or is selected from R′—OH, R′—NR′₂, R′SH, R′CHO, R′CN, R′X, R′N⁺(R′)₃X⁻, R′SiR′₃, R′Si(—OR′—)_{y}R′_{3-y}, R′Si(—O—SiR′₂—)OR′, R′—R″, R′—N—CO, (C₂H₄O—)_{w}H, (—C₃H₆O—)_{w}H, (—C₂H₄O)_{w}—R′, (C₃H₆O)_{w}—R′, R′, and w is an integer greater than one and less than 200.

The adhesive resin in the conductive adhesive layer may comprise an ester resin, a neopentyl glycol (NPG), ethylene glycol (EG), isophthalic acid, a terephthalic acid, a urethane resin, a urethane ester resin, an acrylic resin, an acrylic urethane resin, or a combination thereof.

In some embodiments, the adhesive resin contains a curing agent and/or a coupling agent in an amount of 1 to 30 parts by weight based on 100 parts by weight of the adhesive resin.

The adhesive resin contains a thermally curable resin may contain a polyfunctional epoxy monomer selected from diglycerol tetraglycidyl ether, dipentaerythritol tetraglycidyl ether, sorbitol polyglycidyl ether, polyglycerol polyglycidyl ether, pentaerythritol polyglycidyl ether, or a combination thereof.

In some embodiments, the adhesive resin contains a thermally curable resin containing a bi- or tri-functional epoxy monomer selected from the group consisting of trimethylolethane triglycidyl ether, trimethylolmethane triglycidyl ether, trimethylolpropane triglycidyl ether, triphenylolmethane triglycidyl ether, trisphenol triglycidyl ether, tetraphenylol ethane triglycidyl ether, tetraglycidyl ether of tetraphenylol ethane, p-aminophenol triglycidyl ether, 1,2,6-hexanetriol triglycidyl ether, glycerol triglycidyl ether, diglycerol triglycidyl ether, glycerol ethoxylate triglycidyl ether, castor oil triglycidyl ether, propoxylated glycerine triglycidyl ether, ethylene glycol diglycidyl ether, 1,4-butanediol diglycidyl ether, neopentyl glycol diglycidyl ether, cyclohexanedimethanol diglycidyl ether, dipropylene glycol diglycidyl ether, polypropylene glycol diglycidyl ether, dibromoneopentyl glycol diglycidyl ether, hydrogenated bisphenol A diglycidyl ether, (3,4-epoxycyclohexane) methyl 3,4-epoxycylohexylcarboxylate, and mixtures thereof.

The adhesive resin may contain an UV radiation curable resin or lacquer selected from acrylate and methacrylate oligomers, (meth)acrylate (acrylate and methacrylate), polyhydric alcohols and their derivatives having (meth)acrylate functional groups, including ethoxylated trimethylolpropane tri(meth)acrylate, tripropylene glycol di(meth)acrylate, trimethylolpropane tri(meth)acrylate, diethylene glycol di(meth)acrylate, pentaerythritol tetra(meth)acrylate, pentaerythritol tri(meth)acrylate, dipentaerythritol hexa(meth)acrylate, 1,6-hexanediol di(meth)acrylate, or neopentyl glycol di(meth)acrylate and mixtures thereof, and acrylate and methacrylate oligomers derived from low-molecular weight polyester resin, polyether resin, epoxy resin, polyurethane resin, alkyd resin, spiroacetal resin, epoxy acrylates, polybutadiene resin, and polythiol-polyene resin.

In some embodiments, the adhesive resin contains a conductive polymer selected from the group consisting of polydiacetylene, polyacetylene (PAc), polypyrrole (PPy), polyaniline (PAni), polythiophene (PTh), polyisothionaphthene (PITN), polyheteroarylenvinylene (PArV), wherein the heteroarylene group is selected from thiophene, furan or pyrrole, poly-p-phenylene (PpP), polyphthalocyanine (PPhc) and the like, and their derivatives, and combinations thereof.

The highly conductive graphitic films may be produced directly from either a neat polymer film (defined as a polymer having no filler dispersed therein) or a graphene sheet-reinforced polymer film, with or without a carbonization procedure prior to graphitization. The carbonization procedure required in the prior art processes most typically involves a treatment of a neat polymer film at a carbonization temperature of up to 1,000-1,500° C. in a carbonization furnace for an extended period of time to form a porous, weak, and fragile carbon film that is difficult to handle. This porous carbon film is then retreated from the carbonization furnace and placed into a graphitization furnace, also for a long period of graphitization time. These prior art processes requiring both carbonization and graphitization are time-consuming and energy-intensive.

Alternatively, presumably one could use just a graphitization furnace, which also serves as a carbonization furnace. In other words, one could place a polymer film in such a furnace, wherein the furnace temperature is varied from near room temperature to a carbonization temperature and maintained at the carbonization temperature (e.g. 1,200° C.) for an extended period of time (6-36 hours) to form a porous carbon film. Subsequently, the temperature of the same furnace, containing the porous carbon film therein, is raised to a graphitization temperature (e.g. 2,850° C.) and maintained at this temperature for another long period of time (5-36 hours).

However, there are several problems associated with this alternative approach: All the ultra-high temperature furnaces (e.g. those for graphitization) suffer from significantly reduced operational life if they are subjected to repeated cooling and heating procedures. For instance, such an alternative approach involves cooling (e.g. from2,850° C. to near room temperature or slightly above) to allow for retreating one batch of heat-treated film samples, introducing another batch, and then heating it back up to 2,850° C. to heat-treat this new batch of film samples. The need to repeatedly cool and heat a furnace over a wide temperature range also involves wasting tremendous amounts of energy. It takes time and extra energy to heat a furnace up to the graphitization temperature, and it also consumes extra time and energy (if faster cooling is desired) to cool it down.

It would be best to maintain a graphitization furnace at a graphitization temperature, never having to cool down this furnace (except for the purpose of conducting a periodic maintenance). With the prior art processes for producing graphitic films, this latter approach (of not involving repeated cooling and heating) has not been considered feasible. Contrarily, it is generally believed that one either has to use two separate furnaces (one for carbonization and the other for graphitization) to complete the graphitization of a polymer film or has to repeatedly cool down and heat up the same furnace for two-stage treatments (carbonization and graphitization) of a polymer film.

After extensive and in-depth studies, we have unexpectedly observed that one could use a single graphitization furnace preset at a desired graphitization temperature to successfully graphitize a polymer film (a neat polymer film having no additive dispersed therein, or a polymer composite film having graphene sheets or expanded graphite flakes as a dispersed additive). Such a direct graphitization strategy works well if the polymer has a relatively high char yield or carbon yield (e.g. >40%, preferably >50%). Examples of high char-yield polymers are polyimide, aromatic polyamide, phenolic resin, polyoxadiazole, polybenzoxazole, polybenzobisoxazole, polythiazole, polybenzothiazole, polybenzobisthiazole, poly(p-phenylene vinylene), polybenzimidazole, polybenzobisimidazole, and polyacrylonitrile.

If graphene sheets are used as an additive, even a low char-yield polymer film can be properly graphitized in a single-stage graphitization process (no separate carbonization) using a single graphitization furnace (without having to cool down and heat up the furnace to accommodate another batch of film samples). In fact, the precursor film does not have to be a polymer; it can be just a monomer, oligomer, aromatic organic, coal tar pitch, petroleum pitch, mesophase pitch, etc. These are highly surprising research results and of high utility value. When graphene sheets are present, the minimum char yield appears to be approximately 5% (from 5% to 40%), but a preferred minimum char yield is approximately 20%.

With the presently invented process, the resulting graphitic film typically has a thickness from 100 nm to 200 μm (preferably and more typically from 1 μm to 100 μm, and further more typically and preferably from 5 μm to 50 μm, and most typically from 10 μm to 25 μm). The process comprises directly feeding a precursor polymer film (or other precursor material film, such as pitch or organic), without going through a carbonization step, to a graphitization zone (e.g. in a graphitization furnace) preset at a graphitization temperature no less than 2,200° C. (more typically no less than 2,500° C., further more typically no less than 2,800° C.) for a period of residence time sufficient for directly converting the precursor polymer film to a porous graphitic film having a density from 0.1 g/cm³ to 1.5 g/cm³ (more typically from 0.3 g/cm³ to 1.3 g/cm³, and most typically from 0.5 g/cm³ to 1.0 g/cm³) and then retreating the porous graphitic film from the graphitization zone. The precursor polymer film is preferably a high char-yield polymer (>40% char yield) selected from the group consisting of polyimide, polyamide, phenolic resin, polyoxadiazole, polybenzoxazole, polybenzobisoxazole, polythiazole, polybenzothiazole, polybenzobisthiazole, poly(p-phenylene vinylene), polybenzimidazole, polybenzobisimidazole, polyacrylonitrile, and combinations thereof. In one embodiment, the precursor polymer film has a thickness from 1 μm to 100 μm, more preferably from 10 μm to 50 μm.

Preferably, the precursor polymer film (or other precursor material film) is under a compression stress while residing in the graphitization zone. For instance, this can be conducted by supporting the precursor polymer film on a first refractory material plate and covered by a second refractory material plate to exert a compressive stress to the precursor polymer film prior to placing the resulting sandwich structure into the furnace. This compression stress is maintained or slightly varied while the sandwich structure resides in the graphitization zone. The first refractory material or second refractory material may be selected from a thermally stable material, such as graphite, a refractory metal, or a carbide, oxide, boride, or nitride of a refractory metal element selected from tungsten, zirconium, tantalum, niobium, molybdenum, tantalum, or rhenium. Alternatively, one could place one or a plurality of polymer films, each separated by a plate of refractory material, in a mold (tool or crucible) and then place the mold in a graphitization furnace.

After the direct graphitization treatment, the resulting porous graphitic film is retreated from the furnace or from the graphitization zone. The process preferably further comprises a step of compressing (e.g. roll-pressing) the porous graphitic film to obtain a solid graphitic film having a physical density from 1.5 g/cm³ to 2.26 g/cm³, more typically greater than 1.7 g/cm³, and most typically greater than 1.9 g/cm³.

Preferably, the process is a continuous process that includes feeding the precursor polymer film from a first end of the graphitization zone, continuously or intermittently moving the film from this first end to a second end, and retreating the porous graphitic film from the second end of the graphitization zone (e.g. entering from one end of a graphitization furnace and leaving from another end of the furnace). Preferably, the graphitization zone is at least 5 meters long. In an embodiment, the graphitization zone is at a temperature no less than 2,750° C. and the residence time is from 3 hours to 12 hours.

The precursor polymer film may be a composite film, containing multiple sheets of a graphene material (having a thickness <100 nm, preferably <10 nm, and most preferably <3.4 nm) or expanded graphite flakes (having a thickness >100 nm, by definition) dispersed in the polymer. The graphene material is selected from pristine graphene, oxidized graphene, reduced graphene oxide, fluorinated graphene, hydrogenated graphene, doped graphene, chemically functionalized graphene, or a combination thereof. The graphene material can comprise a single-layer graphene sheet or a multi-layer graphene platelet with a thickness less than 10 nm. The graphene material can comprise a multi-layer graphene platelet with a thickness less than 4 nm. In a desired embodiment, the graphene material comprises a single-layer pristine graphene sheet or a multi-layer pristine graphene platelet with a thickness less than 10 nm and the pristine graphene sheet or pristine graphene platelet contains no oxygen and is produced from a process that does not involve oxidation.

In an embodiment, the precursor matrix polymer of the composite can have a char yield of less than 50% (or even less than 40% or 20%), if this polymer is reinforced with sheets of a graphene material, as opposed to just the neat polymer alone. We have surprisingly observed that the presence of graphene sheets enable successful graphitization of those presumably non-graphitizable or low char-yield polymers. This is likely due to the notion that graphene sheets can serve as “crystal seeds” or nuclei from which graphite crystals are grown, obviating the need for pyrolyzed polymer structure to form nuclei that exceed critical sizes for crystal growth. Such a polymer structure (containing no graphene) requires a high char yield, normally greater than 50%, to be properly carbonized and graphitized.

For the purpose of characterizing the structure of graphitic films, X-ray diffraction patterns were obtained with an X-ray diffractometer by the use of CuKcv radiation. The peak shift and broadening due to the diffractometer were calibrated using a silicon powder standard. The degree of graphitization, g, was calculated from the X-ray pattern using Mering's Eq, d₀₀₂=0.3354 g+0.344 (1−g), where d₀₀₂ is the interlayer spacing of graphite or graphene crystal in nm. This equation is valid only when d₀₀₂ is equal or less than approximately 0.3440 nm.

Another structural index that can be used to characterize the degree of ordering of the presently invented graphitic film derived from a graphene-reinforced precursor material or related graphite crystals is the “mosaic spread,” which is expressed by the full width at half maximum of an X-ray diffraction intensity curve representing the (002) or (004) reflection. This degree of ordering characterizes the graphite crystal size (or grain size), amounts of grain boundaries and other defects, and the degree of preferred grain orientation. A nearly perfect single crystal of graphite is characterized by having a mosaic spread value of 0.2-0.4. Most of our graphitic films have a mosaic spread value in this range of 0.2-0.4 (when obtained with a heat treatment temperature no less than 2,500° C.). However, some values are in the range from 0.4-0.7 if the graphitization is between 2,200 and 2,500° C.

When the graphitization temperature is less than 2,500° C., the resulting solid graphitic film typically has an inter-graphene spacing less than 0.337 nm (as determined by X-ray diffraction), a thermal conductivity of at least 1,200 W/mK, an electrical conductivity no less than 8,000 S/cm, a physical density greater than 1.9 g/cm3, and/or a tensile strength greater than 35 MPa. When the graphitization temperature is higher than 2,500° C., the resulting graphitic film typically has an inter-graphene spacing less than 0.336 nm, a thermal conductivity of at least 1,300 W/mK, an electrical conductivity no less than 10,000 S/cm, a physical density greater than 2.0 g/cm3, and/or a tensile strength greater than 40 MPa.

In an embodiment, the graphitic film exhibits an inter-graphene spacing less than 0.337 nm and a mosaic spread value less than 1.0. In another embodiment, the graphitic film exhibits a degree of graphitization no less than 60% and/or a mosaic spread value less than 0.7. In yet another embodiment, the graphitic film exhibits a degree of graphitization no less than 90% and/or a mosaic spread value less than 0.4.

The preparation of graphene materials and expanded graphite flakes is now described in details as follows:

The constituent graphene planes of a graphite crystallite can be exfoliated and extracted or isolated from a graphite crystallite to obtain individual graphene sheets of carbon atoms provided the inter-planar van der Waals forces can be overcome. An isolated, individual graphene sheet of carbon atoms is commonly referred to as single-layer graphene. A stack of multiple graphene planes bonded through van der Waals forces in the thickness direction with an inter-graphene plane spacing of 0.3354 nm is commonly referred to as a multi-layer graphene. A multi-layer graphene platelet has up to 300 layers of graphene planes (<100 nm in thickness), but more typically up to 30 graphene planes (<10 nm in thickness), even more typically up to 20 graphene planes (<7 nm in thickness), and most typically up to 10 graphene planes (commonly referred to as few-layer graphene in scientific community). Single-layer graphene and multi-layer graphene sheets are collectively called “nanographene platelets” (NGPs). Graphene sheets/platelets or NGPs are a new class of carbon nanomaterial (a 2-D nanocarbon) that is distinct from the 0-D fullerene, the 1-D CNT, and the 3-D graphite. The graphene planes can be made to contain other elements, such as hydrogen, nitrogen, oxygen, and fluoride, to obtain hydrogenated graphene, nitrogenated graphene, graphene oxide, and graphene fluoride, as four examples of graphene materials.

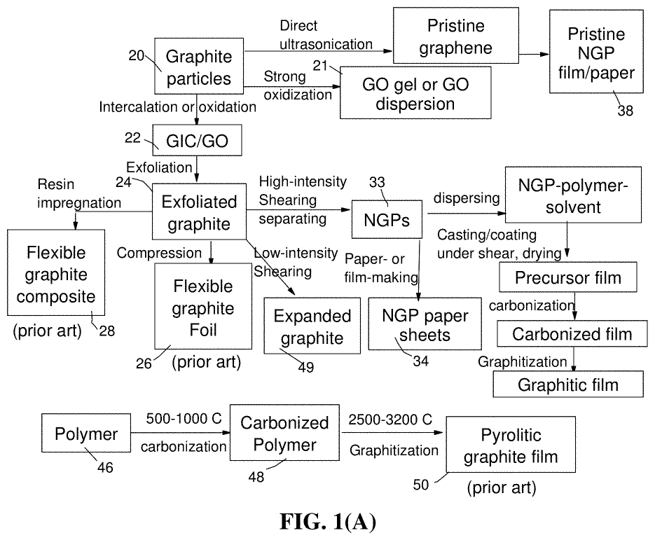

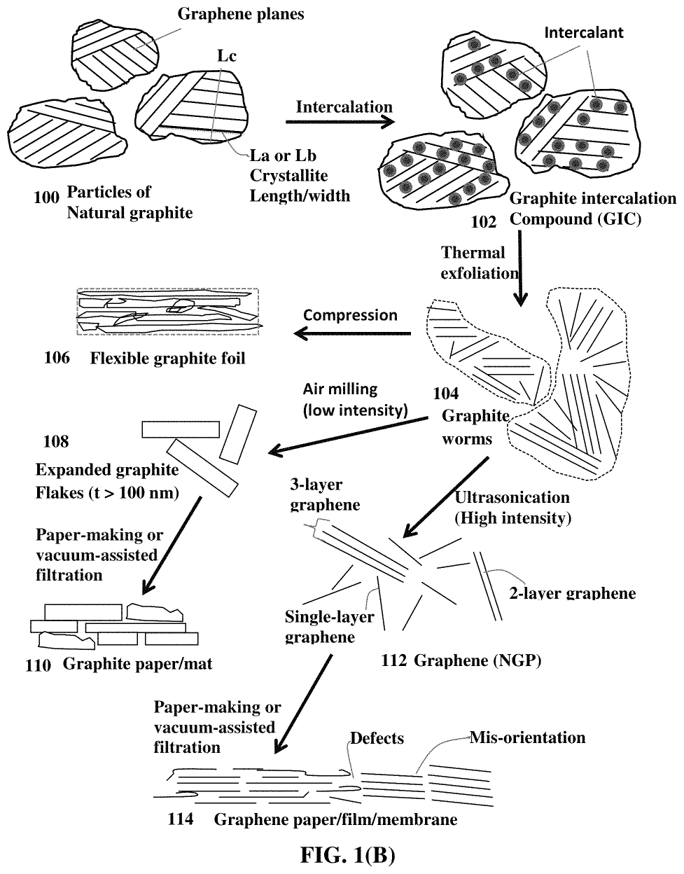

NGPs are typically obtained by intercalating natural graphite particles with a strong acid and/or oxidizing agent to obtain a graphite intercalation compound (GIC) or graphite oxide (GO), as illustrated in FIGS. 1(A) and 1(B). The presence of chemical species or functional groups in the interstitial spaces between graphene planes serves to increase the inter-graphene spacing (d₀₀₂, as determined by X-ray diffraction), thereby significantly reducing the van der Waals forces that otherwise hold graphene planes together along the c-axis direction. The GIC or GO is most often produced by immersing natural graphite powder (20 in FIG. 1(A)) in a mixture of sulfuric acid, nitric acid (an oxidizing agent), and another oxidizing agent (e.g. potassium permanganate or sodium perchlorate). The resulting GIC (22) is actually some type of graphite oxide (GO) particles. This GIC is then repeatedly washed and rinsed in water to remove excess acids, resulting in a graphite oxide suspension or dispersion, which contains discrete and visually discernible graphite oxide particles dispersed in water. There are two processing routes to follow after this rinsing step:

Route 1 involves removing water from the suspension to obtain “expandable graphite,” which is essentially a mass of dried GIC or dried graphite oxide particles. Upon exposure of expandable graphite to a temperature in the range from typically 800-1,050° C. for approximately 30 seconds to 2 minutes, the GIC undergoes a rapid expansion by a factor of 30-300 to form “graphite worms” (24), which are each a collection of exfoliated, but largely un-separated graphite flakes that remain interconnected.

In Route 1A, these graphite worms (exfoliated graphite or “networks of interconnected/non-separated graphite flakes”) can be re-compressed to obtain flexible graphite sheets or foils (26) that typically have a thickness in the range from 0.1 mm (100 μm)-0.5 mm (500 μm).

Alternatively, one may choose to use a low-intensity air jet mill or shearing machine to simply break up the graphite worms for the purpose of producing the so-called “expanded graphite flakes” which contain mostly graphite flakes or platelets thicker than 100 nm (hence, not a nanomaterial by definition). Expanded graphite flakes may also be added to a polymer matrix material to make a composite film. Such an expanded graphite-polymer film can also be graphitized under comparable conditions as graphene-reinforced polymer composite film. However, the expanded graphite-polymer derived graphitic film exhibits a thermal conductivity and electrical conductivity lower than those of graphene sheet-reinforced polymer derived graphitic film having a comparable additive loading.

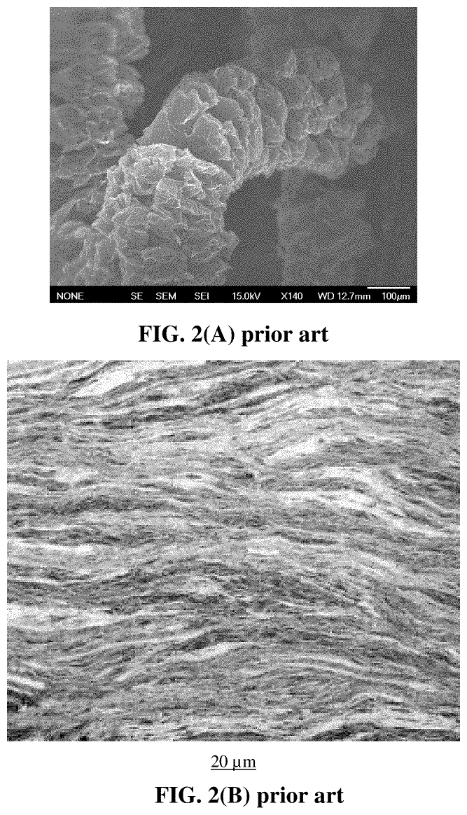

Exfoliated graphite worms, expanded graphite flakes, and the recompressed mass of graphite worms (commonly referred to as flexible graphite sheet or flexible graphite foil) are all 3-D graphitic materials that are fundamentally different and patently distinct from either the 1-D nanocarbon material (CNT or CNF) or the 2-D nanocarbon material (graphene sheets or platelets, NGPs). Flexible graphite (FG) foils can be used as a heat spreader material, but exhibiting a maximum in-plane thermal conductivity of typically less than 500 W/mK (more typically <300 W/mK) and in-plane electrical conductivity no greater than 1,500 S/cm. These low conductivity values are a direct result of the many defects, wrinkled or folded graphite flakes, interruptions or gaps between graphite flakes, and non-parallel flakes (e.g. SEM image in FIG. 2(B)). Many flakes are inclined with respect to one another at a very large angle (e.g. mis-orientation of 20-40 degrees).

In Route 1B, the exfoliated graphite is subjected to high-intensity mechanical shearing (e.g. using an ultrasonicator, high-shear mixer, high-intensity air jet mill, or high-energy ball mill) to form separated single-layer and multi-layer graphene sheets (collectively called NGPs, 33). Single-layer graphene can be as thin as 0.34 nm, while multi-layer graphene can have a thickness up to 100 nm. In the present application, the thickness of multi-layer NGPs is typically less than 20 nm.

Route 2 entails ultrasonicating the graphite oxide suspension for the purpose of separating/isolating individual graphene oxide sheets from graphite oxide particles. This is based on the notion that the inter-graphene plane separation has been increased from 0.3354 nm in natural graphite to 0.6-1.1 nm in highly oxidized graphite oxide, significantly weakening the van der Waals forces that hold neighboring planes together. Ultrasonic power can be sufficient to further separate graphene plane sheets to form separated, isolated, or discrete graphene oxide (GO) sheets. These graphene oxide sheets can then be chemically or thermally reduced to obtain “reduced graphene oxides” (RGO) typically having an oxygen content of 0.001%-10% by weight, more typically 0.01%-5% by weight.

For the purpose of defining the claims of the instant application, NGPs include discrete sheets/platelets of single-layer and multi-layer versions of graphene, graphene oxide, or reduced graphene oxide with an oxygen content of 0-10% by weight, more typically 0-5% by weight, and preferably 0-2% by weight. Pristine graphene has essentially 0% oxygen. Graphene oxide (including RGO) typically has 0.001%-46% by weight of oxygen. NGPs or graphene materials can also include graphene fluoride, graphene chloride, graphene bromide, graphene iodide, nitrogenated graphene, hydrogenated graphene, doped graphene (e.g. boron-doped graphene), and functionalized graphene (e.g. amine-functionalized, polymer functionalized, etc.).

Pristine graphene may be produced by direct ultrasonication (also known as liquid phase production) or supercritical fluid exfoliation of graphite particles. These processes are well-known in the art. Multiple pristine graphene sheets may be dispersed in water or other liquid medium with the assistance of a surfactant to form a suspension. A chemical blowing agent may then be dispersed into the dispersion (38 in FIG. 1(A)). This suspension is then cast or coated onto the surface of a solid substrate (e.g. glass sheet or Al foil). When heated to a desired temperature, the chemical blowing agent is activated or decomposed to generate volatile gases (e.g. N₂ or CO₂), which act to form bubbles or pores in an otherwise mass of solid graphene sheets, forming a pristine graphene foam 40a.

Fluorinated graphene or graphene fluoride is herein used as an example of the halogenated graphene material group. There are two different approaches that have been followed to produce fluorinated graphene: (1) fluorination of pre-synthesized graphene: This approach entails treating graphene prepared by mechanical exfoliation or by CVD growth with fluorinating agent such as XeF₂, or F-based plasmas; (2) Exfoliation of multilayered graphite fluorides: Both mechanical exfoliation and liquid phase exfoliation of graphite fluoride can be readily accomplished.

Interaction of F₂ with graphite at high temperature leads to covalent graphite fluorides (CF)ₙ or (C₂F)ₙ, while at low temperatures graphite intercalation compounds (GIC) CₓF (2≤x≤24) form. In (CF)ₙ carbon atoms are sp3-hybridized and thus the fluorocarbon layers are corrugated consisting of trans-linked cyclohexane chairs. In (C₂F)ₙ only half of the C atoms are fluorinated and every pair of the adjacent carbon sheets are linked together by covalent C—C bonds. Systematic studies on the fluorination reaction showed that the resulting F/C ratio is largely dependent on the fluorination temperature, the partial pressure of the fluorine in the fluorinating gas, and physical characteristics of the graphite precursor, including the degree of graphitization, particle size, and specific surface area. In addition to fluorine (F₂), other fluorinating agents may be used, although most of the available literature involves fluorination with F₂ gas, sometimes in presence of fluorides.

For exfoliating a layered precursor material to the state of individual layers or few-layers, it is necessary to overcome the attractive forces between adjacent layers and to further stabilize the layers. This may be achieved by either covalent modification of the graphene surface by functional groups or by non-covalent modification using specific solvents, surfactants, polymers, or donor-acceptor aromatic molecules. The process of liquid phase exfoliation includes ultra-sonic treatment of a graphite fluoride in a liquid medium.

The nitrogenation of graphene can be conducted by exposing a graphene material, such as graphene oxide, to ammonia at high temperatures (200-400° C.). Nitrogenated graphene could also be formed at lower temperatures by a hydrothermal method; e.g. by sealing GO and ammonia in an autoclave and then increased the temperature to 150-250° C. Other methods to synthesize nitrogen doped graphene include nitrogen plasma treatment on graphene, arc-discharge between graphite electrodes in the presence of ammonia, ammonolysis of graphene oxide under CVD conditions, and hydrothermal treatment of graphene oxide and urea at different temperatures.

Once graphene sheets or graphene oxide sheets are made, they can be readily formed into graphene paper using any known paper-making method (e.g. vacuum-assisted filtration of graphene or GO sheets), graphene fabric (e.g. spinning of GO suspension, followed by any non-woven or weaving procedures), graphene films (e.g. via casting, coating, spraying, etc.), and other thin sheet forms.

The following examples are presented to illustrate the best modes of practicing the instant invention, and not to be construed as limiting the scope of the instant invention:

### EXAMPLE 1

### Preparation of Discrete Graphene Sheets (Nanographene Platelets, or NGPs) and Expanded Graphite Flakes

Natural graphite powder with an average lateral dimension of 45 μm was used as a starting material, which was immersed in a mixture of concentrated sulfuric acid, nitric acid, and potassium permanganate (as the chemical intercalate and oxidizer) to prepare graphite intercalation compounds (GICs). The starting material was first dried in a vacuum oven for 24 h at 80° C. Then, a mixture of concentrated sulfuric acid, fuming nitric acid, and potassium permanganate (at a weight ratio of 4:1:0.05) was slowly added, under appropriate cooling and stirring, to a three-neck flask containing fiber segments. After 16 hours of reaction, the acid-treated natural graphite particles were filtered and washed thoroughly with deionized water until the pH level of the solution reached 4.0. After being dried at 100° C. overnight, the resulting graphite intercalation compound (GIC) was subjected to a thermal shock at 1050° C. for 45 seconds in a tube furnace to form exfoliated graphite (or graphite worms).

Five grams of the resulting exfoliated graphite (graphite worms) were mixed with 2,000 ml alcohol solution consisting of alcohol and distilled water with a ratio of 65:35 for 2 hours to obtain a suspension. Then the mixture or suspension was subjected to ultrasonic irradiation with a power of 200 W for various times. After two intermittent sonication treatments each of 1.5 hours, EG particles were effectively fragmented into thin NGPs. The suspension was then filtered and dried at 80° C. to remove residue solvents. The as-prepared NGPs (thermally reduced GO) have an average thickness of approximately 3.4 nm.

Another five grams of the resulting exfoliated graphite worms were subjected to low-intensity air jet milling to break up graphite worms, forming expanded graphite flakes (having an average thickness of 139 nm).

Both graphene sheets and expanded graphite flakes were respectively added into an adhesive resin to make conductive adhesives, which were sprayed, cast, or coated onto a pre-made graphitic film or graphene layer to form a thin layer of conductive adhesive deposited thereon. Another graphitic film or graphene layer was then laid over the conductive adhesive layer-covered graphitic film or graphene layer to form a three-layer laminate (e.g. graphitic film/conductive adhesive/graphitic film, graphene layer/conductive adhesive/graphene layer, graphitic film/conductive adhesive/graphene layer, etc.). Multiple-layer laminates were made in a similar manner. The laminate was then heated and exposed to UV to cure the adhesive resin. In some cases, UV exposure of the adhesive resin was conducted to initiate the curing reactions prior to being sandwiched between two graphitic films or graphene layers.

Some of the more heavily oxidized GIC or graphite oxide was then re-dispersed in water to obtain slurry sample s, which were then subjected to ultrasonication for 10-60 minutes to obtain graphene oxide slurries. The slurry was then coated onto a solid substrate surface, dried, peeled off, and thermally treated to obtain unitary or integrated graphene films according to known procedures (e.g. U.S. Pat. No. 9,533,889 (Jan. 3, 2017)). These films were used as the constituent graphene layers in the invented multilayer laminates.

### EXAMPLE 2

### Preparation of Single-Layer Graphene Sheets from Mesocarbon Microbeads (MCMBs)

Mesocarbon microbeads (MCMBs) were supplied from China Steel Chemical Co. This material has a density of about 2.24 g/cm³ with a median particle size of about 16 μm. MCMB (10 grams) were intercalated with an acid solution (sulfuric acid, nitric acid, and potassium permanganate at a ratio of 4:1:0.05) for 72 hours. Upon completion of the reaction, the mixture was poured into deionized water and filtered. The intercalated MCMBs were repeatedly washed in a 5% solution of HCl to remove most of the sulfate ions. The sample was then washed repeatedly with deionized water until the pH of the filtrate was neutral. The slurry was dried and stored in a vacuum oven at 60° C. for 24 hours. The dried powder sample was placed in a quartz tube and inserted into a horizontal tube furnace pre-set at a desired temperature, 1,080° C. for 45 seconds to obtain a graphene material. TEM and atomic force microscopic studies indicate that most of the NGPs were single-layer graphene.

These graphene sheets were added into a wide variety of adhesive resins to prepare thermally and UV-curable adhesives.

Some of the graphene sheets were re-dispersed into water containing a dispersing agent to form a suspension. The suspension was then poured into the trough of a vacuum-assisted filtration device to make a sheet of graphene paper. Graphene paper sheets were roll-pressed to produce graphene paper layers having a higher degree of graphene orientation.

### EXAMPLE 3

### Preparation of Pristine Graphene Sheets/Platelets

In a typical procedure, five grams of graphite flakes, ground to approximately 20 μm or less in sizes, were dispersed in 1,000 mL of deionized water (containing 0.1% by weight of a dispersing agent, Zonyl® FSO from DuPont) to obtain a suspension. An ultrasonic energy level of 85 W (Branson 5450 Ultrasonicator) was used for exfoliation, separation, and size reduction of graphene sheets for a period of 15 minutes to 2 hours. These pristine graphene sheets were used as a conductive additive in an adhesive resin. Some of the pristine sheets were made into graphene paper using a well-known vacuum-assisted filtration procedure.

### EXAMPLE 4

### Preparation of Graphene Fluoride Nanosheets

Several processes have been used by us to produce GF, but only one process is herein described as an example. In a typical procedure, highly exfoliated graphite (HEG) was prepared from intercalated compound C₂F.xClF₃. HEG was further fluorinated by vapors of chlorine trifluoride to yield fluorinated highly exfoliated graphite (FHEG). Pre-cooled Teflon reactor was filled with 20-30 mL of liquid pre-cooled ClF₃, the reactor was closed and cooled to liquid nitrogen temperature. Then, no more than 1 g of HEG was put in a container with holes for ClF₃ gas to access and situated inside the reactor. In 7-10 days a gray-beige product with approximate formula C₂F was formed.

Subsequently, a small amount of FHEG (approximately 0.5 mg) was mixed with 20-30 mL of an organic solvent (methanol, ethanol, 1-propanol, 2-propanol, 1-butanol, tert-butanol, isoamyl alcohol) and subjected to an ultrasound treatment (280 W) for 30 min, leading to the formation of homogeneous yellowish dispersions. Five minutes of sonication was enough to obtain a relatively homogenous dispersion of few-layer graphene fluoride, but longer sonication times ensured the production of mostly single-layer graphene fluoride sheets. Some of these suspension samples were subjected to vacuum oven drying to recover separated graphene fluoride sheets. These graphene fluoride sheets were then added into a polymer-solvent or monomer-solvent solution to form a suspension. Various polymers or monomers (or oligomers) were utilized as the precursor film materials for subsequent direct graphitization or, for comparison purposes, for subsequent carbonization and graphitization treatments.

Upon casting on a glass surface with the solvent removed, the dispersion became a brownish film formed on the glass surface. When these GF-reinforced polymer films were heat-treated, fluorine and other non-carbon elements were released as gases that generated pores in the film. The resulting porous graphitic films had physical densities from 0.33 to 1.22 g/cm³. These porous graphitic films were then roll-pressed to obtain solid graphitic films having a density from 1.8 to 2.2 g/cm³.

### EXAMPLE 5

### Preparation of Nitrogenated Graphene Nanosheets

Graphene oxide (GO), synthesized in Example 2, was finely ground with different proportions of urea and the pelletized mixture heated in a microwave reactor (900 W) for 30 s. The product was washed several times with deionized water and vacuum dried. In this method graphene oxide gets simultaneously reduced and doped with nitrogen. The products obtained with graphene:urea mass ratios of 1:0.5, 1:1 and 1:2 are designated as NGO-1, NGO-2 and NGO-3 respectively and the nitrogen contents of these samples were 14.7, 18.2 and 17.5 wt % respectively as found by elemental analysis. These nitrogenated graphene sheets remain dispersible in water. Two types of dispersions were then prepared. One involved adding water-soluble polymer (e.g. polyethylene oxide) into the nitrogenated graphene sheet-water dispersion to produce a water-based suspension. The other involved drying the nitrogenated graphene sheet-water dispersion to recover nitrogenated graphene sheets, which were then added into precursor polymer-solvent solutions to obtain organic solvent-based suspensions.

The resulting suspensions were then cast, dried, and then either directly graphitized or carbonized and then graphitized. The carbonization temperatures for comparative samples are 900-1,350° C. The graphitization temperatures are from 2,200° C. to 2,950° C.

### EXAMPLE 6

### Preparation of Polybenzoxazole (PBO) Films, Graphene (NGP)-PBO Films, and Expanded Graphite Flake-PBO Films

Polybenzoxazole (PBO) films were prepared via casting and thermal conversion from its precursor, methoxy-containing polyaramide (MeO-PA). Specifically, monomers of 4,4′-diamino-3,3′-dimethoxydiphenyl (DMOBPA), and isophthaloyl dichloride (IPC) were selected to synthesize PBO precursors, methoxy-containing polyaramide (MeO-PA) solution. This MeO-PA solution for casting was prepared by polycondensation of DMOBPA and IPC in DMAc solution in the presence of pyridine and LiCl at −5° C. for 2 hr, yielding a 20 wt % pale yellow transparent MeO-PA solution. The inherent viscosity of the resultant MeO-PA solution was 1.20 dL/g measured at a concentration of 0.50 g/dl at 25° C. This MeO-PA solution was diluted to a concentration of 15 wt % by DMAc for casting.

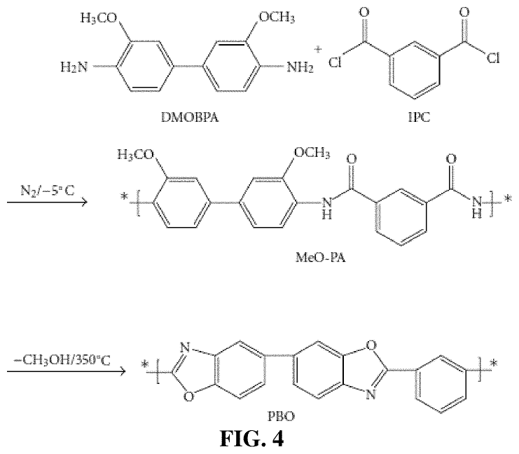

The as-synthesized MeO-PA was cast onto a glass surface to form thin films (35-120 μm) under a shearing condition. The cast film was dried in a vacuum oven at 100° C. for 4 hr to remove the residual solvent. Then, the resulting film having a thickness of approximately 28-100 μm was treated at 200° C.-350° C. under N₂ atmosphere in three steps and annealed for about 2 hr at each step. This heat treatment serves to thermally convert MeO-PA into PBO films. The chemical reactions involved may be illustrated in FIG. 4. For comparison, both graphene (NGP)-PBO and expanded graphite flake (EP)-PBO films were made under similar conditions. The graphene sheet or EP flake proportions were varied from 10% to 90% by weight.

For comparison purposes, selected film samples were pressed between two plates of alumina while being carbonized under a 3-sccm argon gas flow in three steps: from room temperature to 600° C. in 1 h, from 600 to 1,000° C. in 1.5 h, and maintained at 1,000° C. for 5 hours. The carbonized films were then roll-pressed in a pair of rollers to reduce the thickness by approximately 40%. The roll-pressed films were then subjected to graphitization treatments at 2,200° C. for 5 hours, followed by another round of roll-pressing to reduce the thickness by typically 20-40%. For direct graphitization samples, there was no carbonization step, and the samples were directly placed in a furnace pre-set at 2,200° C. and maintained at this temperature for 5 hours before the furnace was cooled down and samples retreated.

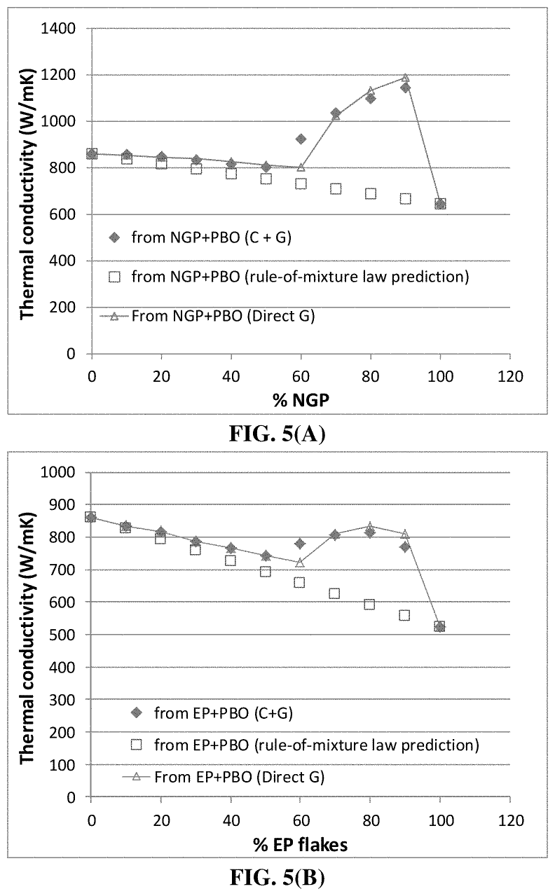

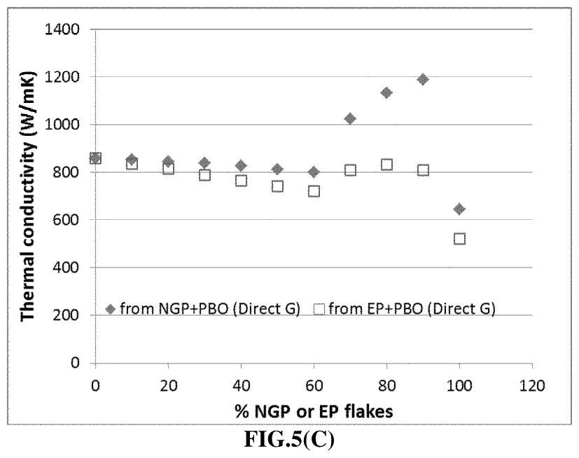

The thermal conductivity values of a series of graphitic films derived from NGP-PBO films of various NGP (graphene material) weight fractions (from 0% to 100%) prepared under different processing conditions (direct graphitization and “carbonization+graphitization”) are summarized in FIG. 5(A). Also plotted therein is a curve of thermal conductivity (K_{c}) according to the theoretical predictions of a rule-of-mixture law commonly used to predict the property of a composite consisting of two components A and B having thermal conductivity of K_{A} and K_{B}, respectively: K_{c}=w_{A} K_{A}+w_{B} K_{B}, where w_{A}=weight fraction of component A and w_{B}=weight fraction of component B, and w_{A}+w_{B}=1. In the present case, w_{B}=weight fraction of NGPs, varying from 0% to 100%. The sample containing 100% NGPs was prepared by a well-known vacuum-assisted filtration procedure for making graphene paper, which was also allowed to undergo the same heat treatment and roll-pressing procedures. Several observations can be made by examining these data:
(A) The data clearly indicate that direct graphitization (without carbonization) leads to graphitic films exhibiting comparable or even better thermal conductivity as compared to the graphitic films prepared through combined carbonization and graphitization. Yet, the direct graphitization requires a significantly shorter period of time (shorter by as much as 36 hours) and consumes a significantly lesser amount of energy.
(B) For both direct graphitization and combined carbonization/graphitization approaches, the approach of adding graphene sheets into a precursor polymer matrix led to unexpected synergism, having all thermal conductivity values drastically higher than those theoretically predicted based on the rule-of-mixture law.
(C) Further significantly and unexpectedly, some thermal conductivity values are higher than those of both the film derived from PBO alone (860 W/mK) and the film (paper) derived from graphene sheets alone (645 W/mK). With 60-90% NGP (graphene sheets) in the precursor composite film, the thermal conductivity values of the final graphitic films are above 860 W/mK, the better (higher) of the two.
(D) Quite interestingly, the neat PBO-derived graphitic films prepared under identical conditions exhibit a highest conductivity value of 860 W/mK, yet several combined NGP-PBO films, when carbonized and graphitized, exhibit thermal conductivity values of 924-1,145 W/mK. When directly graphitized, the thermal films derived from PBO-NGP exhibit a thermal conductivity as high as 1,200 W/mK.

These surprisingly observed synergistic effects might be due to the notions that graphene sheets could promote graphitization of the heat-treated precursor material (e.g. PBO film), and that the newly graphitized phase from PBO could help fill the gaps between otherwise separated discrete graphene sheets. Graphene sheets are themselves a highly graphitic material, better organized or graphitized than the graphitized polymer itself. Without the newly formed graphitic domains that bridge the gaps between graphene sheets, the transport of electrons and phonons would have been interrupted and would have resulted in lower conductivity. This is why the thin film paper made from NGPs alone exhibits a conductivity of only 645 W/mK.

The thermal conductivity values of a series of graphitic films derived from EP-PBO films of various weight fractions of expanded graphite flakes (EP, from 0% to 100%) are summarized in FIG. 5(B). Again, direct graphitization gives rise to a graphitic film as good as conventional combined carbonization/graphitization treatments that are otherwise dramatically more time-consuming and energy intensive. Also plotted therein is a curve of thermal conductivity (K_{c}) according to the theoretical predictions of a rule-of-mixture law. The data also show that the approach of adding expanded graphite flakes into a precursor polymer film has led to synergism, having all thermal conductivity values higher than the rule-of-mixture law predictions. However, as re-plotted in FIG. 5(C), these deviations from the theoretical predictions are not as dramatic as those in NGP-filled counterparts. This is quite surprising by itself since expanded graphite flakes (>100 nm in thickness) are actually quite graphitic, no less graphitic or organized than graphene sheets (typically 0.34-10 nm thick). This might be due to graphene sheets being more readily oriented during the film-forming procedure as compared to expanded graphite flakes. Additionally, graphene sheets might also be more effective than expanded graphite flakes in promoting graphitization of the precursor material; e.g. being more effective heterogeneous nucleating sites for graphite crystals.

### EXAMPLE 7

### Preparation of Polyimide (PI) Films, NGP-PI Films, and Their Heat Treated Versions

The synthesis of conventional polyimide (PI) involved poly(amic acid) (PAA, Sigma Aldrich) formed from pyromellitic dianhydride (PMDA) and oxydianiline (ODA). Prior to use, both chemicals were dried in a vacuum oven at room temperature. Then, 4 g of the monomer ODA was dissolved into 21 g of DMF solution (99.8 wt %). This solution was stored at 5° C. before use. PMDA (4.4 g) was added, and the mixture was stirred for 30 min using a magnetic bar. Subsequently, the clear and viscous polymer solution was separated into four samples. Triethyl amine catalyst (TEA, Sigma Aldrich) with 0, 1, 3, and 5 wt % was then added into each sample to control the molecular weight. Stirring was maintained by a mechanical stirrer until the entire quantity of TEA was added. The as-synthesized PAA was kept at −5° C. to maintain properties essential to further processing.

Solvents utilized in the poly(amic acid) synthesis are an important consideration. Common dipolar aprotic amide solvents utilized are DMF, DMAc, NMP and TMU. DMAc was a preferred solvent utilized in the present study. The intermediate poly(amic acid) and NGP-PAA precursor composite were converted to the final polyimide by the thermal imidization route. Films were first cast on a glass substrate and then allowed to proceed through a thermal cycle with temperatures ranging from 100° C. to 350° C. The procedure entails heating the poly(amic acid) mixture to 100° C. and holding for one hour, heating from 100° C. to 200° C. and holding for one hour, heating from 200° C. to 300° C. and holding for one hour and slow cooling to room temperature from 300° C.

The PI films, pressed between two alumina plates, were heat-treated under a 3-sccm argon gas flow at 1000° C. This occurred in three steps: from room temperature to 600° C. in 1 h, from 600 to 1,000° C. in 2 h, and 1,000° C. maintained for 5 h. The carbonized samples were then graphitized. Separately, selected samples were subjected to direct graphitization without a pre-carbonization treatment. The graphitization or direct graphitization temperatures were varied from 2,200 to 2,950° C.

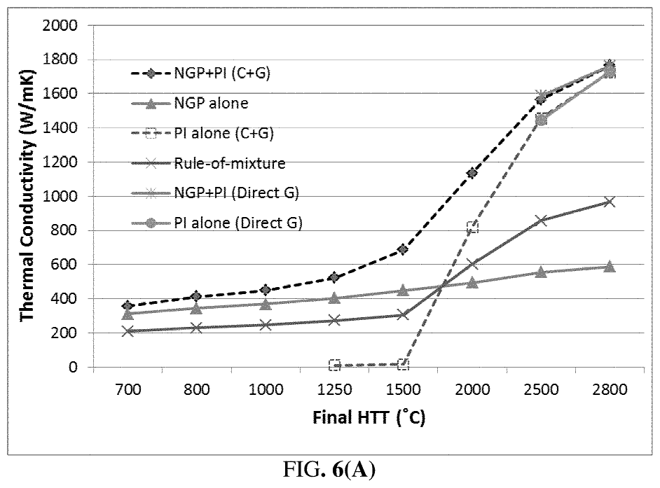

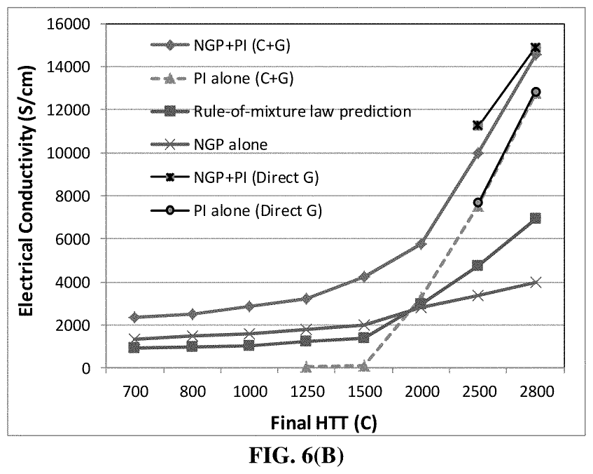

The thermal conductivity and electrical conductivity values of a series of graphitic films derived from NGP-PI films (66% NGP+34% PI), NGP paper alone, and PI film alone each prepared under various heat treatment conditions are summarized in FIG. 6(A) and FIG. 6(B), respectively. Also plotted in each figure is a curve of thermal conductivity (K_{c}) or electrical conductivity curve according to the predictions of a rule-of-mixture law. These data clearly demonstrate that direct graphitization (without carbonization) leads to graphitic films exhibiting comparable or even better thermal conductivity as compared to the graphitic films prepared through combined carbonization and graphitization. Yet, the direct graphitization requires a significantly shorter period of time and consumes a significantly lesser amount of energy. The data also demonstrate that the approach of incorporating graphene sheets in a precursor material (PI) has led to synergism, having all thermal and electrical conductivity values higher than the rule-of-mixture law predictions. Not just thermal conductivity, but also electrical conductivity can be significantly improved.

The graphitic films obtained from these PI or PI composite films were then incorporated into various multi-layer laminates.

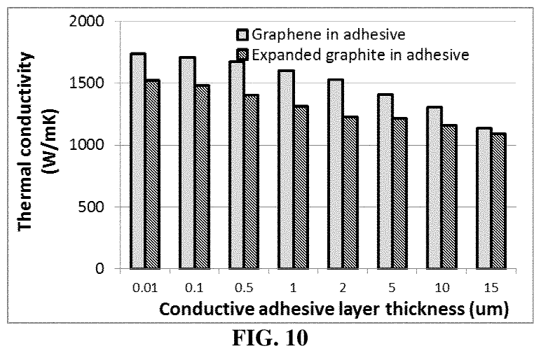

Shown in FIG. 10 are the thermal conductivity values of a series of graphitic 3-layer laminates each containing a conductive adhesive layer (having either 10% by weight of graphene sheets or 10% by weight of expanded graphite flakes dispersed therein) sandwiched between two graphitic films, wherein the adhesive layer has a thickness varied from 10 nm to 15 μm. These data indicate that the overall in-plane thermal conductivity of the multi-layer laminates decrease with increasing adhesive layer thickness. This trend is particularly severe if the adhesive layer thickness exceeds 1 μm. Similar trends were observed for graphitic laminates containing other types of graphitic films (derived from different polymer precursors) or graphene layers (graphene paper, graphene films, graphene fabric, etc.)

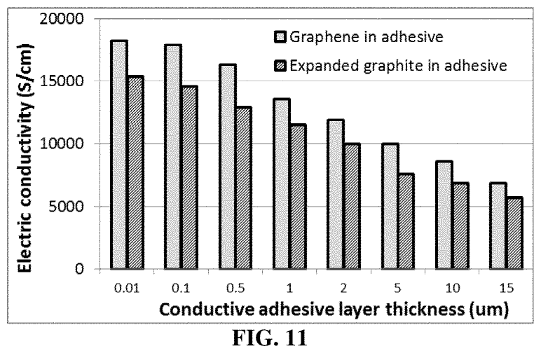

Summarized in FIG. 11 are the electrical conductivity values of a series of graphitic 3-layer laminates each containing a conductive adhesive layer (having either 10% by weight of graphene sheets or 10% by weight of expanded graphite flakes dispersed therein) sandwiched between two graphitic films, wherein the adhesive layer has a thickness varied from 10 nm to 15 μm. These data again indicate the significant negative impact of the adhesive layer thickness. The overall in-plane electrical conductivity of the multi-layer laminates decrease with increasing adhesive layer thickness. This trend is particularly severe if the adhesive layer thickness exceeds 1 μm.

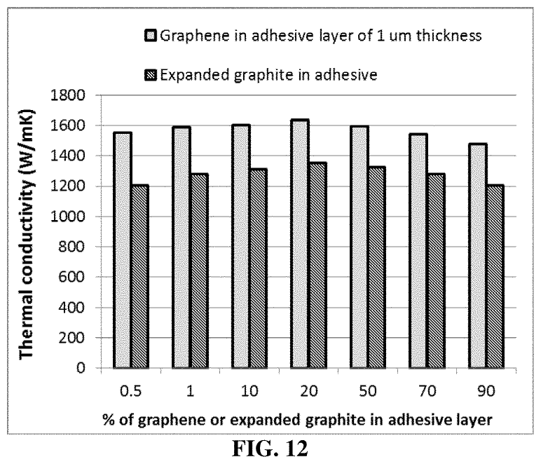

FIG. 12 shows the thermal conductivity values of a series of graphitic 3-layer laminates each containing a conductive adhesive layer (having either graphene sheets or expanded graphite flakes dispersed therein) sandwiched between two graphitic films, wherein the adhesive layer has a thickness of approximately 1 μm and graphene/expanded graphite proportion varied from 0.5% to 90%. These data indicate that higher amounts of graphene sheets or expanded graphite flakes are not always desired or beneficial. The optimal proportion of these conductive additives in the conductive adhesive layer is approximately 20% by weight.

### EXAMPLE 8

### Preparation of Phenolic Resin, NGP-Phenolic Films, and Their Heat-Treated Versions

Phenol formaldehyde resins (PF) are synthetic polymers obtained by the reaction of phenol or substituted phenol with formaldehyde. The PF resin, alone or with up to 90% by weight NGPs or expanded graphite (EP) flakes, was made into 50-μm thick film and cured under identical curing conditions: a steady isothermal cure temperature at 100° C. for 2 hours and then increased from 100 to 170° C. and maintained at 170° C. to complete the curing reaction.

Some of the thin films were then subjected to direct graphitization at two different temperatures (2,500 and 2,800° C.) for 6 hours. For comparison, other thin films were carbonized at 500° C. for 2 hours, at 700° C. for 3 hours, and at 1,000° C. for 3 hours. The carbonized films were then subjected to further heat treatments (graphitization) at temperatures that were varied from 1,500 to 2,800° C. for 6-10 hours.

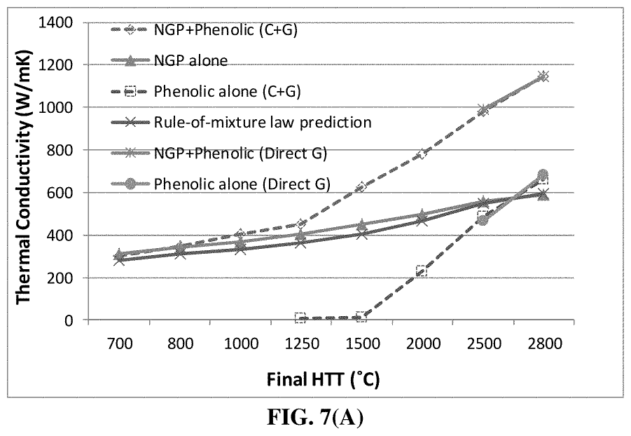

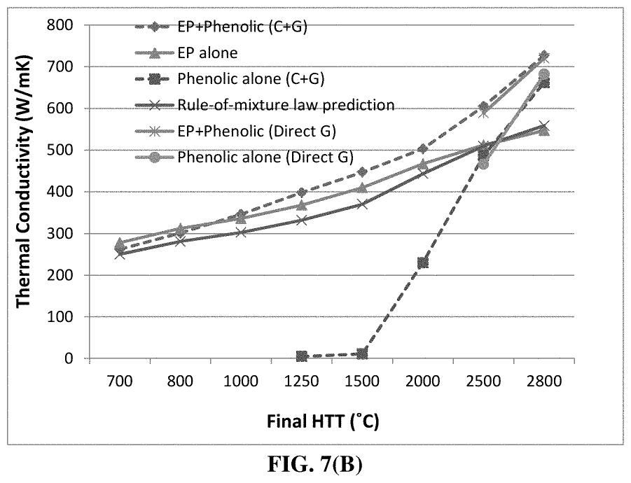

The thermal conductivity values of a series of graphitic films derived from NGP-PF films (e.g. 90% NGP+10% PF), NGP paper alone, and PF film alone prepared at various final heat treatment temperatures are summarized in FIG. 7(A). Also plotted therein is a curve of thermal conductivity (K_{c}) according to the predictions of a rule-of-mixture law. It is clear that direct graphitization is a much preferred process to combined carbonization/graphitization treatments since it provides comparable graphic films at a much faster production rate and much lower energy consumption. Again, the data show that the approach of incorporating graphene sheets and a graphite precursor (PF) has led to synergism, having all thermal conductivity values much higher than the rule-of-mixture law predictions.

The thermal conductivity values of a series of graphitic films derived from expanded graphite flake (EP)-PF films (90% EP+10% PI), EP paper alone, and PF film alone prepared at various final heat treatment temperatures are summarized in FIG. 7(B). Also plotted therein is a curve of thermal conductivity (K_{c}) according to the predictions of a rule-of-mixture law. The data show that the approach of combining expanded graphite flakes and a carbon precursor (PF) has led to synergism, having all thermal conductivity values higher than the rule-of-mixture law predictions. However, as re-plotted in FIG. 7(C), these deviations from the theoretical predictions are not as dramatic as those in NGP-filled counterparts. Again, this is quite surprising by itself since expanded graphite flakes are actually quite graphitic, no less graphitic or organized than graphene sheets. This might be due to graphene sheets being more readily oriented during the film-forming procedure as compared to expanded graphite flakes. Additionally, graphene sheets might also be more effective than expanded graphite in promoting graphitization of the carbonized precursor material; e.g. being more effective heterogeneous nucleating sites for graphite crystals during graphitization of the carbonized resin.

The graphitic films obtained from these polymers or polymer composite films were then incorporated into various multi-layer laminates. The conductive adhesive resin was sprayed, cast, or coated over a graphitic film or graphene layer and the adhesive-covered film/layer was then covered with another graphitic film or graphene layer to form a 3-layer laminate. Another layer of conductive adhesive was the sprayed, cast, or coated over the surface of this third layer, which was then further laminated with yet another graphitic film or graphene layer to make a 5-layer structure. Other multi-layer laminates may be produced in a similar manner.

### EXAMPLE 9

### Preparation of Polybenzimidazole (PBI) Films and NGP-PBI Films

PBI is prepared by step-growth polymerization from 3,3′,4,4′-tetraaminobiphenyl and diphenyl isophthalate (an ester of isophthalic acid and phenol). The PBI used in the present study was obtained from PBI Performance Products in a PBI solution form, which contains 0.7 dl/g PBI polymer dissolved in dimethylacetamide (DMAc). The PBI and NGP-PBI films were cast onto the surface of a glass substrate. The heat treatment and roll-pressing procedures were similar to those used in Example 7 for PBO.

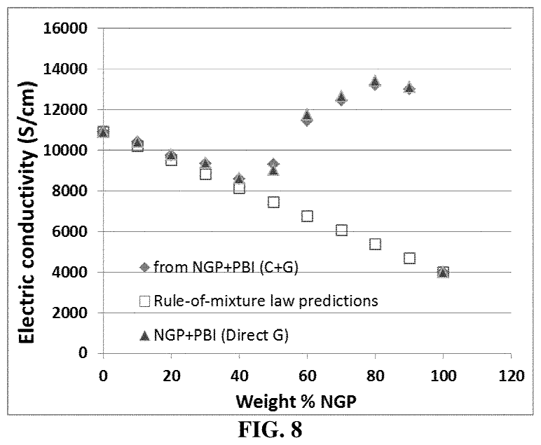

The electric conductivity values of a series of graphitic films derived from NGP-PBI films of various weight fractions of NGPs (from 0% to 100%) are summarized in FIG. 8. Also plotted therein is a curve of electric conductivity (σ_{c}) according to the predictions of a rule-of-mixture law commonly used to predict the property of a composite consisting of two components A and B having electric conductivity of σ_{A} and σ_{B}, respectively: σ_{c}=w_{A} σ_{A}+w_{B} σ_{B}, where w_{A}=weight fraction of component A and w_{B}=weight fraction of component B, and w_{A}+w_{B}=1. In the present case, w_{B}=weight fraction of NGPs, varying from 0% to 100%. The sample containing 100% NGPs was prepared by a well-known vacuum-assisted filtration procedure for making graphene paper which also underwent the same heat treatment and roll-pressing procedures.

The data further validates the presently invented direct graphitization strategy in terms of producing superior graphitic films from a polymer film without going through a tedious and energy intensive carbonization stage. The data clearly demonstrate that the approach of combining NGP and a precursor material, followed by direct graphitization, led to dramatic synergism, having all electric conductivity values drastically higher than those theoretically predicted based on the rule-of-mixture law. Further unexpectedly, some electric conductivity values are higher than those of both the film derived from PBI alone (10,900 S/cm) and the paper derived from graphene sheets alone (3,997 S/cm). With 60-90% NGP in the precursor composite film, the electric conductivity values of the final graphitic films are above 10,900 S/cm, the better (higher) of the two. Quite interestingly, even though the neat PBI-derived graphitic films prepared under identical conditions exhibit a highest conductivity value of 10,900 S/cm, several combined NGP-PBI films, upon direct graphitization, exhibit electric conductivity values of 11,755-13,435 S/cm.

The graphitic films obtained from these polymers or polymer composite films were then incorporated into various multi-layer laminates. The conductive adhesive resin was sprayed, cast, or coated over a graphitic film or graphene layer and the adhesive-covered film/layer was then covered with another graphitic film or graphene layer to form a 3-layer laminate. Another layer of conductive adhesive was the sprayed, cast, or coated over the surface of this third layer, which was then further laminated with yet another graphitic film or graphene layer to make a 5-layer structure. Other multi-layer laminates may be produced in a similar manner.

### EXAMPLE 10

### Graphitic Films From Various NGP-Modified Carbon/Graphite Precursors

Additional graphitic films are prepared from several different types of precursor materials. Their electric and thermal conductivity values are listed in Table 1 below. These data further confirm that direct graphitization is a superior process for producing superior graphitic films from graphene-reinforced precursor materials.

TABLE 1
Preparation conditions and properties of graphitic films from other
precursor materials

| | | | | | Electric | Thermal |
|---|---|---|---|---|---|---|
| Sample | | Carbon | Carbonization | Graphitization | conduc. | conduc. |
| No. | NGP or EP | Precursor | temperature | temperature | (S/cm) | (W/mK) |
| 8-A | Pristine | Petroleum | 600-1000° C. | 2,300° C. | 8,300 | 950 |
| | graphene, 80% | pitch | | | | |
| 8-B | Pristine | Petroleum | none | 2,300 | 8,350 | 953 |
| | graphene, 80% | pitch | | | | |
| 8-C | EP, 80% | Coal tar | 600-1000° C. | 2,300 | 6,776 | 766 |
| | | pitch | | | | |
| 8-D | EP, 80% | Coal tar | none | 2,300 | 6,770 | 765 |
| | | pitch | | | | |
| 9-A | Reduced GO, | Naphthalene | 600-1000° C. | 2,300 | 7,322 | 855 |
| | 80% | | | | | |
| 9-B | Reduced GO, | Naphthalene | none | 2,300 | 7,330 | 860 |
| | 80% | | | | | |
| 10-A | Fluorinated | PAN | 230, 600, | 2,500 | 7,007 | 820 |
| | graphene, 50% | | 1000° C. | | | |
| | | | each 1 hr | | | |
| 10-B | Fluorinated | PAN | none | 2,500 | 7,011 | 825 |
| | graphene, 50% | | | | | |
| 10-C | Fluorinated | None | 230, 600, | 2,500 | 3,233 | 520 |
| | graphene paper | | 1000° C. | | | |
| | | | each 1 hr | | | |
| 11-A | Nitrogenated | Polyamide | 600-1,500° C. | 2,800 | 9,540 | 1,050 |
| | graphene, 85% | | | | | |
| 11-B | Nitrogenated | Polyamide | none | 2,800 | 9,550 | 1,065 |
| | graphene, 85% | | | | | |

### EXAMPLE 11

### Characterization of Graphitic Films and Multi-Layer Laminates

X-ray diffraction curves of a carbonized or graphitized material were monitored as a function of the heat treatment temperature and time. The peak at approximately 2θ=22-23° of an X-ray diffraction curve corresponds to an inter-graphene spacing (d₀₀₂) of approximately 0.3345 nm in natural graphite. With some heat treatment at a temperature>1,500° C. of a carbonized aromatic polymer, such as PI, PBI, and PBO, the material begins to see diffraction curves exhibiting a peak at 2θ<12° C. The angle 2θ shifts to higher values when the graphitization temperature and/or time are increased. With a heat treatment temperature of 2,500° C. for 1-5 hours (in a direct graphitization process or combined carbonization/graphitization procedures), the d₀₀₂ spacing typically is decreased to approximately 0.336 nm, close to 0.3354 nm of a graphite single crystal.

With a heat treatment temperature of 2,750° C. for 5 hours, the d₀₀₂ spacing is decreased to approximately to 0.3354 nm, identical to that of a graphite single crystal. In addition, a second diffraction peak with high intensity appears at 2θ=55°, corresponding to X-ray diffraction from (004) plane. The (004) peak intensity relative to the (002) intensity on the same diffraction curve, or the I(004)/I(002) ratio, is a good indication of the degree of crystal perfection and preferred orientation of graphene planes.

The (004) peak is either non-existing or relatively weak, with the I(004)/I(002) ratio<0.1, for all graphitic materials obtained from neat matrix polymers (containing no dispersed NGPs) via heat treating at a final temperature lower than 2,800° C. For these materials, the I(004)/I(002) ratio for the graphitic materials obtained by heat treating at 3,000-3,250° C. is in the range from 0.2-0.5. In contrast, a graphitic film prepared from a NGP-PI film (90% NGP) with a HTT of 2,750° C. for 3 hours exhibits a I(004)/I(002) ratio of 0.78 and a Mosaic spread value of 0.21, indicating a practically perfect graphene single crystal with an exceptional degree of preferred orientation.

The “mosaic spread” value is obtained from the full width at half maximum of the (002) reflection in an X-ray diffraction intensity curve. This index for the degree of ordering characterizes the graphite or graphene crystal size (or grain size), amounts of grain boundaries and other defects, and the degree of preferred grain orientation. A nearly perfect single crystal of graphite is characterized by having a mosaic spread value of 0.2-0.4. Most of our NGP-PI derived materials have a mosaic spread value in this range of 0.2-0.4 (if obtained with a heat treatment temperature no less than 2,200° C.). It may be noted that the I(004)/I(002) ratio for flexible graphite foil are typically <<0.05, practically non-existing in most cases. The I(004)/I(002) ratio for all NGP paper/membrane samples is <0.1 even after a heat treatment at 3,000° C. for 2 hours.

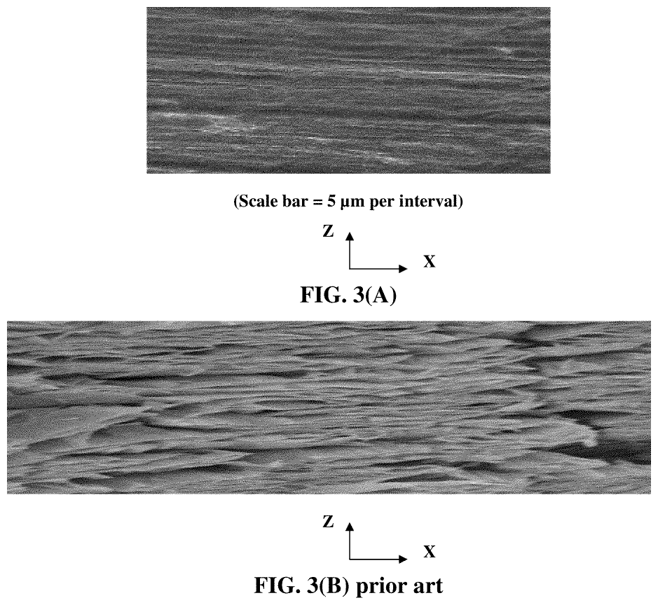

Scanning electron microscopy (SEM), transmission electron microscopy (TEM) pictures of lattice imaging of the graphene layer, as well as selected-area electron diffraction (SAD), bright field (BF), and dark-field (DF) images were also conducted to characterize the structure of various graphitic film materials. A close scrutiny and comparison of FIGS. 2(A), 3(A), and 3(B) indicates that the graphene layers in a graphitic film herein invented are substantially oriented parallel to one another; but this is not the case for flexible graphite foils and NGP paper. The inclination angles between two identifiable layers in the inventive graphitic films are mostly less than 5 degrees. In contrast, there are so many folded graphite flakes, kinks, and mis-orientations in flexible graphite that many of the angles between two graphite flakes are greater than 10 degrees, some as high as 45 degrees (FIG. 2(B)). Although not nearly as bad, the mis-orientations between graphene platelets in NGP paper (FIG. 3(B)) are also high and there are many gaps between platelets. Most significantly, the inventive graphitic films are essentially gap-free.

### EXAMPLE 12

### Tensile Strength of Various Graphitic Films and Multi-Layer Laminates

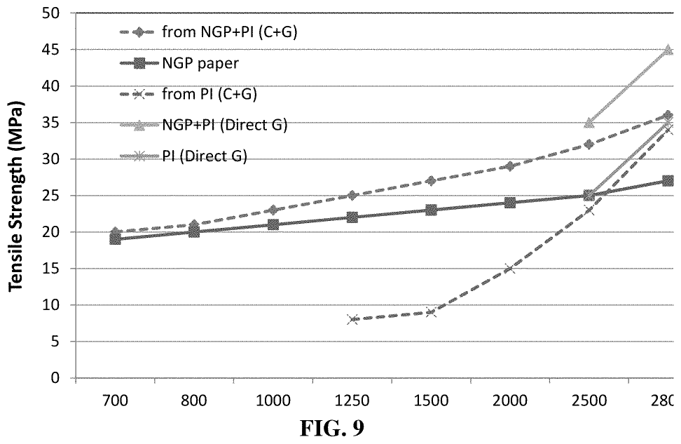

A universal testing machine was used to determine the tensile strength of these materials. The tensile strength values of NGP-PI derived films, PI-derived films, and NGP paper samples are plotted as a function of the graphitization temperature, FIG. 9. These data demonstrate that the tensile strength of the PI film are very low (<<10 MPa) unless the final heat treatment temperature exceeds 2,000° C. The strength of the NGP paper increases slightly (from 19 to 27 MPa) when the heat treatment temperature increases from 700 to 2,800° C. In contrast, the tensile strength of the NGP-reinforced PI derived films obtained via combined carbonization and graphitization increases significantly from 20 to36 MPa over the same range of heat treatment temperatures. The corresponding films obtained via direct graphitization exhibit even higher strength values, some as high as 45 MPa.

In conclusion, we have successfully developed an absolutely new, novel, unexpected, and patently distinct class of graphitic laminates and a process for producing such highly conducting graphitic thick films. The thin films produced with this process have the best combination of excellent electrical conductivity, thermal conductivity, and mechanical strength.

We claim:

1. A multi-layer graphitic laminate comprising at least two carbon-based layers selected from graphitic films and graphene layers and a layer of conductive adhesive disposed between said carbon-based layers and bonded thereto, wherein said conductive adhesive layer comprises graphene sheets or expanded graphite flakes and an adhesive resin, and said graphene sheets or expanded graphite flakes occupy a weight fraction from 0.01% to 99% based on the total conductive adhesive weight.

2. The multi-layer graphitic laminate of claim 1, wherein said laminate has a thickness from 20 μm to 500 μm, said conductive adhesive layer has a thickness from 5 nm to 15 μm, and/or said graphitic films or graphene layers have a thickness greater than 20 μm.

3. The multi-layer graphitic laminate of claim 1, having an in-plane thermal conductivity from 1,200 to 1,750 W/mK or an in-plane electric conductivity from 2,000 to 20,000 S/cm.

4. The multi-layer graphitic laminate of claim 1, wherein said conductive adhesive layer has a thickness from 10 nm to 2 μm.

5. The multi-layer graphitic laminate of claim 1, having a physical density from 1.5 g/cm³ to 2.26 g/cm³ when comprising no metallic, ceramic, or glass filler dispersed therein.

6. The multi-layer graphitic laminate of claim 1, wherein said graphene sheets contain single-layer or few-layer graphene sheets selected from a pristine graphene material having essentially zero % of non-carbon elements, or a non-pristine graphene material having 0.001% to 25% by weight of non-carbon elements wherein said non-pristine graphene is selected from the group consisting of graphene oxide, reduced graphene oxide, graphene fluoride, graphene chloride, graphene bromide, graphene iodide, hydrogenated graphene, nitrogenated graphene, doped graphene, chemically functionalized graphene, and combinations thereof.

7. The multi-layer graphitic laminate of claim 1, wherein said graphene sheets comprise chemically functionalized graphene sheets having a chemical functional group the group consisting of alkyl or aryl silane, alkyl or aralkyl group, hydroxyl group, carboxyl group, carboxylic group, amine group, sulfonate group (—SO₃H), aldehydic group, quinoidal, fluorocarbon, and combinations thereof.

8. The multi-layer graphitic laminate of claim 1, wherein said graphene sheets comprise chemically functionalized graphene sheets having a chemical functional group selected from a derivative of an azide compound selected from the group consisting of 2-azidoethanol, 3-azidopropan-1-amine, 4-(2-azidoethoxy)-4-oxobutanoic acid, 2-azidoethyl-2-bromo-2-methylpropanoate, chlorocarbonate, azidocarbonate, dichlorocarbene, carbene, aryne, nitrene, (R-)-oxycarbonyl nitrenes, where R=any one of the following groups, 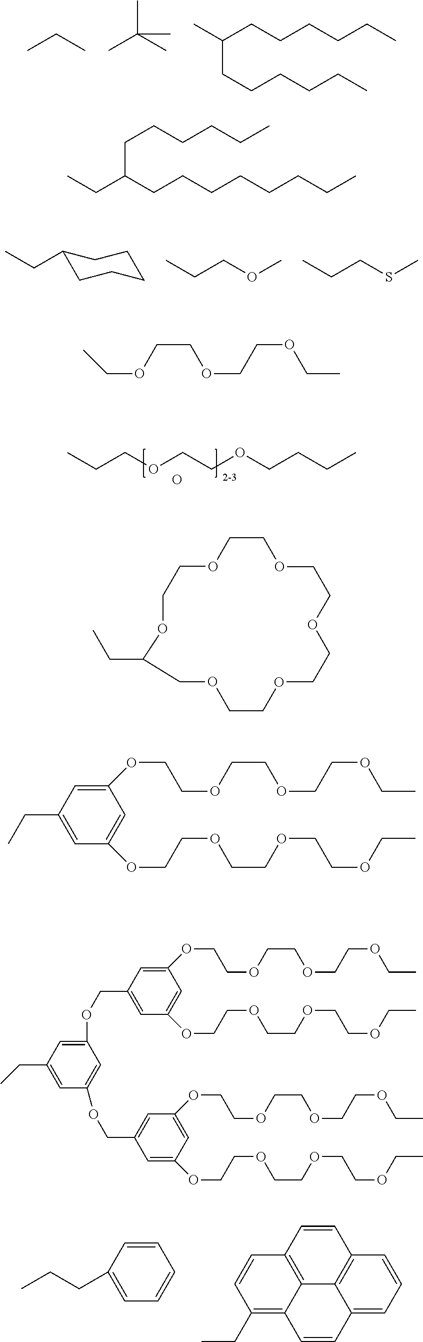
and combinations thereof.

9. The multi-layer graphitic laminate of claim 1, wherein said graphene sheets comprise chemically functionalized graphene sheets having a chemical functional group selected from an oxygenated group selected from the group consisting of hydroxyl, peroxide, ether, keto, and aldehyde.

10. The multi-layer graphitic laminate of claim 1, wherein said graphene sheets contain chemically functionalized graphene sheets having a chemical functional group selected from the group consisting of —SO₃H, —COOH, —NH₂, —OH, —R′CHOH, —CHO, —CN, —COCl, halide, —COSH, —SH, —COOR′, —SR′, —SiR′₃, —Si(—OR′—)_{y}R′₃-y, —Si(—O—SiR′₂—)OR′, —R″, Li, AlR′₂, Hg—X, TlZ₂ and Mg—X; wherein y is an integer equal to or less than 3, R′ is hydrogen, alkyl, aryl, cycloalkyl, or aralkyl, cycloaryl, or poly(alkylether), R″ is fluoroalkyl, fluoroaryl, fluorocycloalkyl, fluoroaralkyl or cycloaryl, X is halide, and Z is carboxylate or trifluoroacetate, and combinations thereof.

11. The multi-layer graphitic laminate of claim 1, wherein said graphene sheets comprise chemically functionalized graphene sheets having a chemical functional group selected from the group consisting of amidoamines, polyamides, aliphatic amines, modified aliphatic amines, cycloaliphatic amines, aromatic amines, anhydrides, ketimines, diethylenetriamine (DETA), triethylene-tetramine (TETA), tetraethylene-pentamine (TEPA), polyethylene polyamine, polyamine epoxy adduct, phenolic hardener, non-brominated curing agent, non-amine curatives, and combinations thereof.

12. The multi-layer graphitic laminate of claim 1, wherein said graphene sheets contain chemically functionalized graphene sheets having a chemical functional group selected from OY, NHY, O═C—OY, P═C—NR′Y, O═C—SY, O═C—Y, —CR′1-OY, N′Y or C′Y, and Y is a functional group of a protein, a peptide, an amino acid, an enzyme, an antibody, a nucleotide, an oligonucleotide, an antigen, or an enzyme substrate, enzyme inhibitor or the transition state analog of an enzyme substrate or is selected from R′—OH, R′—NR′₂, R′SH, R′CHO, R′CN, R′X, R′N⁺(R′)₃X⁻, R′SiR′₃, R′Si(—OR′—)_{y}R′_{3-y}, R′Si(—O—SiR′₂—)OR′, R′—R″, R′—N—CO, (C₂H₄O—)_{w}H, (—C₃H₆O—)_{w}H, (—C₂H₄O)_{w}—R′, (C₃H₆O)_{w}—R′, R′, and w is an integer greater than one and less than 200.

13. The multi-layer graphitic laminate of claim 1, wherein said expanded graphite flakes have a thickness from 100 nm to 1 μm or chemically functionalized.

14. The multi-layer graphitic laminate of claim 1, wherein said adhesive resin includes an ester resin, a neopentyl glycol (NPG), ethylene glycol (EG), isophthalic acid, a terephthalic acid, a urethane resin, a urethane ester resin, an acrylic resin, an acrylic urethane resin, or a combination thereof.

15. The multi-layer graphitic laminate of claim 1, wherein said adhesive resin contains a curing agent and/or a coupling agent in an amount of 1 to 30 parts by weight based on 100 parts by weight of the adhesive resin.

16. The multi-layer graphitic laminate of claim 1, wherein said adhesive resin contains a thermally curable resin containing a polyfunctional epoxy monomer selected from diglycerol tetraglycidyl ether, dipentaerythritol tetraglycidyl ether, sorbitol polyglycidyl ether, polyglycerol polyglycidyl ether, pentaerythritol polyglycidyl ether, or a combination thereof.

17. The multi-layer graphitic laminate of claim 1, wherein said adhesive resin contains a thermally curable resin containing a bi- or tri-functional epoxy monomer selected from the group consisting of trimethylolethane triglycidyl ether, trimethylolmethane triglycidyl ether, trimethylolpropane triglycidyl ether, triphenylolmethane triglycidyl ether, trisphenol triglycidyl ether, tetraphenylol ethane triglycidyl ether, tetraglycidyl ether of tetraphenylol ethane, p-aminophenol triglycidyl ether, 1,2,6-hexanetriol triglycidyl ether, glycerol triglycidyl ether, diglycerol triglycidyl ether, glycerol ethoxylate triglycidyl ether, castor oil triglycidyl ether, propoxylated glycerine triglycidyl ether, ethylene glycol diglycidyl ether, 1,4-butanediol diglycidyl ether, neopentyl glycol diglycidyl ether, cyclohexanedimethanol diglycidyl ether, dipropylene glycol diglycidyl ether, polypropylene glycol diglycidyl ether, dibromoneopentyl glycol diglycidyl ether, hydrogenated bisphenol A diglycidyl ether, (3,4-epoxycyclohexane) methyl 3,4-epoxycylohexylcarboxylate, and mixtures thereof.

18. The multi-layer graphitic laminate of claim 1, wherein said adhesive resin contains an UV radiation curable resin or lacquer selected from acrylate and methacrylate oligomers, (meth)acrylate (acrylate and methacrylate), polyhydric alcohols and their derivatives having (meth)acrylate functional groups, including ethoxylated trimethylolpropane tri(meth)acrylate, tripropylene glycol di(meth)acrylate, trimethylolpropane tri(meth)acrylate, diethylene glycol di(meth)acrylate, pentaerythritol tetra(meth)acrylate, pentaerythritol tri(meth)acrylate, dipentaerythritol hexa(meth)acrylate, 1,6-hexanediol di(meth)acrylate, or neopentyl glycol di(meth)acrylate and mixtures thereof, and acrylate and methacrylate oligomers derived from low-molecular weight polyester resin, polyether resin, epoxy resin, polyurethane resin, alkyd resin, spiroacetal resin, epoxy acrylates, polybutadiene resin, and polythiol-polyene resin.

19. The multi-layer graphitic laminate of claim 1, wherein said adhesive resin contains a conductive polymer selected from the group consisting of polydiacetylene, polyacetylene (PAc), polypyrrole (PPy), polyaniline (PAni), polythiophene (PTh), polyisothionaphthene (PITN), polyheteroarylenvinylene (PArV), wherein the heteroarylene group is selected from thiophene, furan or pyrrole, poly-p-phenylene (PpP), polyphthalocyanine (PPhc) and the like, and their derivatives, and combinations thereof.

20. The multi-layer graphitic laminate of claim 1, wherein the graphitic film exhibits a degree of graphitization no less than 60% and/or a mosaic spread value less than 0.7.

21. The multi-layer graphitic laminate of claim 1, wherein the graphitic film exhibits a degree of graphitization no less than 90% and/or a mosaic spread value less than 0.4.

22. An electronic device containing a multi-layer graphitic laminate of claim 1 as a heat-dissipating element therein.
